(19) United States
(12) Patent Application Publication
(10) Pub. No.: US 2025/0185398 A1
(43) Pub. Date: Jun. 5, 2025

(54) IMAGE SENSOR AND ELECTRONIC SYSTEM INCLUDING THE SAME

(71) Applicant: SAMSUNG ELECTRONICS CO., LTD., Suwon-si (KR)

(72) Inventor: Kooktae KIM, Suwon-si (KR)

(73) Assignee: SAMSUNG ELECTRONICS CO., LTD., Suwon-si (KR)

(21) Appl. No.: 18/786,158

(22) Filed: Jul. 26, 2024

(30) Foreign Application Priority Data
Nov. 30, 2023 (KR) 10-2023-0171819
Jun. 7, 2024 (KR) 10-2024-0074578

(51) Int. Cl. H01L 27/146

(52) U.S. Cl. CPC H10F 39/807; H10F 39/011; H10F 39/182; H10F 39/199; H10F 39/8053; H10F 39/8063; H10F 39/811

(57) ABSTRACT

An image sensor includes a plurality of unit pixels on a substrate, and a pixel isolation structure extending through the substrate in a vertical direction and defining the plurality of unit pixels, where the pixel isolation structure includes a line isolation portion linearly extending along a side of and between each of two adjacent unit pixels of the plurality of unit pixels, a corner isolation portion contacting a corner of each of at least two adjacent unit pixels of the plurality of unit pixels, a first conductive pattern surrounding a first air gap in the line isolation portion, and a first insulating pattern surrounding the first air gap and the first conductive pattern in the line isolation portion, and a width of the first insulating pattern in a lateral direction varies along the vertical direction.

### CROSS-REFERENCE TO RELATED APPLICATION

This application is based on and claims priority under 35 U.S.C. § 119 to Korean Patent Application No. 10-2023-0171819 filed on Nov. 30, 2023 and Korean Patent Application No. 10-2024-0074578 filed on Jun. 7, 2024 in the Korean Intellectual Property Office, the disclosures of which are incorporated herein by reference in their entireties.

### BACKGROUND

Example embodiments of the disclosure relate to an image sensor and an electronic system including the same, and more particularly, to an image sensor including a pixel isolation structure configured to isolate sensing areas from each other and an electronic system including the image sensor.

With the development of the computer industry and the communication industry, image sensors that acquire images and convert the acquired images into electrical signals have been used in various devices, such as digital cameras, camcorders, personal communication systems (PCS), game devices, security cameras, and medical micro cameras. As image sensors become highly integrated and pixel sizes are miniaturized, to implement high-sensitivity image sensors, a width of pixels that are sensing areas has been gradually decreased, a height thereof has been gradually increased, and an aspect ratio of a pixel isolation structure configured to isolate the pixels from each other has also increased. In addition, as the integration density of the image sensors has increased and a size of each of the plurality of pixels has been reduced, new techniques may be needed to effectively control characteristics (e.g., a dark current and white spots) in the plurality of pixels and improve sensitivity.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide an image sensor having a structure that may effectively control characteristics (e.g., a dark current and white spots) and improve sensitivity in each of a plurality of unit pixels.

One or more example embodiments further provide an electronic system including an image sensor having a structure that may effectively control characteristics (e.g., a dark current and white spots) and improve sensitivity in each of a plurality of unit pixels.

Additional aspects will be set forth in part in the description which follows and, in part, will be apparent from the description, or may be learned by practice of the presented embodiments.

According to an aspect of an example embodiment, an image sensor may include a plurality of unit pixels on a substrate, and a pixel isolation structure extending through the substrate in a vertical direction and defining the plurality of unit pixels, where the pixel isolation structure may include a line isolation portion linearly extending along a side of and between each of two adjacent unit pixels of the plurality of unit pixels, a corner isolation portion contacting a corner of each of at least two adjacent unit pixels of the plurality of unit pixels, a first conductive pattern surrounding a first air gap in the line isolation portion, and a first insulating pattern surrounding the first air gap and the first conductive pattern in the line isolation portion, and a width of the first insulating pattern in a lateral direction may vary along the vertical direction.

According to an aspect of an example embodiment, an image sensor may include a plurality of unit pixels in a substrate including a frontside surface and a backside surface, each of the plurality of unit pixels respectively including a photodiode and the plurality of unit pixels having a two-dimensional array structure in a matrix form along a plurality of row lines and a plurality of column lines, and a pixel isolation structure including a main device isolation film extending through the substrate from the frontside surface of the substrate to the backside surface of the substrate in a vertical direction and defining the plurality of unit pixels, the main device isolation film including a line isolation portion and a corner isolation portion, a local device isolation film extending through a portion of the substrate from the frontside surface of the substrate in the vertical direction and covering at least as portion of a sidewall of the main device isolation film which is adjacent to the frontside surface of the substrate, a first conductive pattern surrounding a first air gap in the line isolation portion, a first insulating pattern surrounding the first air gap and the first conductive pattern in the line isolation portion, a second conductive pattern in the corner isolation portion, the second conductive pattern being integrally connected to the first conductive pattern, and a second insulating pattern in the corner isolation portion, the second insulating pattern surrounding the second conductive pattern and being integrally connected to the first insulating pattern, where each of the first insulating pattern and the second insulating pattern has a tapered cross-sectional shape with a width gradually increasing in a lateral direction from the backside surface of the substrate toward the frontside surface of the substrate, and each of the first conductive pattern and the second conductive pattern has a width gradually increasing in the lateral direction from the frontside surface of the substrate toward the backside surface of the substrate.

According to an aspect of an example embodiment, an electronic system may include at least one camera module including an image sensor, and a processor configured to process image data provided by the at least one camera module, where the image sensor may include a plurality of unit pixels on a substrate, and a pixel isolation structure extending through the substrate in a vertical direction and defining the plurality of unit pixels, where the pixel isolation structure may include a line isolation portion linearly extending along a side of and between each of two adjacent unit pixels of the plurality of unit pixels, a corner isolation portion contacting a corner of each of at least two adjacent unit pixels of the plurality of unit pixels, a first conductive pattern surrounding a first air gap in the line isolation portion, and a first insulating pattern surrounding the first air gap and the first conductive pattern in the line isolation portion, and a width of the first insulating pattern in a lateral direction varies along the vertical direction.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is an exploded perspective view illustrating an image sensor according to one or more example embodiments;

FIG. 2 is a block diagram illustrating components of an image sensor according to one or more example embodiments;

FIG. 3 is a cross-sectional view illustrating a partial region of an image sensor according to one or more example embodiments;

FIG. 4 is a plan view illustrating a pixel isolation structure included in an image sensor according to one or more example embodiments;

FIG. 5A is an enlarged cross-sectional view illustrating a partial region of a semiconductor chip included in an image sensor according to one or more example embodiments;

FIG. 5B is an enlarged cross-sectional view illustrating partial regions of FIG. 5A according to one or more example embodiments;

FIGS. 6A to 6C are cross-sectional views illustrating image sensors according to one or more example embodiments;

FIGS. 7A, 7B, 8, 9A, 9B, 9C, 10, 11, 12, and 13 are cross-sectional views illustrating image sensors according to one or more example embodiments;

FIGS. 14A to 14N are cross-sectional views illustrating a method of manufacturing an image sensor, according to one or more example embodiments;

FIG. 14O is a cross-sectional view illustrating a modified example of the method of manufacturing the image sensor, which is described with reference to FIGS. 14A to 14N, according to one or more example embodiments;

FIGS. 15A to 15C are cross-sectional views illustrating a method of manufacturing an image sensor, according to one or more example embodiments;

FIGS. 16A to 16F are cross-sectional views illustrating a method of manufacturing an image sensor, according to one or more example embodiments;

FIGS. 17A to 17J are cross-sectional views illustrating a method of manufacturing an image sensor, according to one or more example embodiments;

FIGS. 18A and 18B are cross-sectional views illustrating a method of manufacturing an image sensor, according to one or more example embodiments;

FIG. 19A is a block diagram illustrating an electronic system according to one or more example embodiments; and

FIG. 19B is a block diagram illustrating a camera module included in an electronic system according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

It will be understood that, although the terms first, second, etc. may be used herein to describe various elements, these elements should not be limited by these terms. These terms are only used to distinguish one element from another. Unless otherwise defined, a first element may be termed a second element. For example, a first insulating pattern could be termed a second insulating pattern, and similarly, a second insulating pattern could be termed a first insulating pattern, without departing from the scope of various embodiments described below. Each of the first insulating pattern and the second insulating pattern may be an insulating pattern, but the first insulating pattern and the second insulating pattern may not be the same insulating patterns.

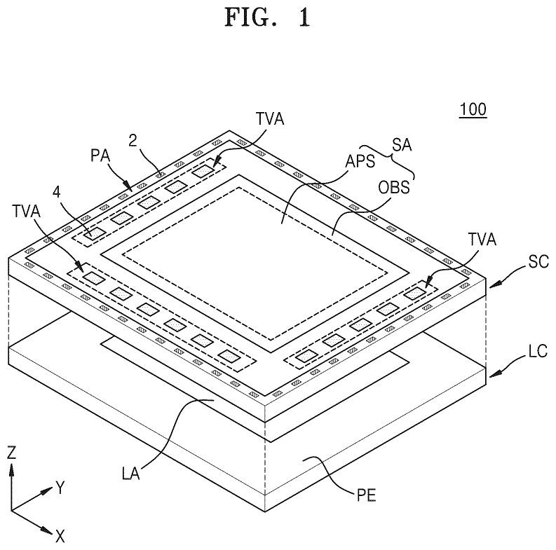

FIG. 1 is an exploded perspective view illustrating an image sensor 100 according to one or more example embodiments.

Referring to FIG. 1, the image sensor 100 may include a first semiconductor chip LC and a second semiconductor chip SC that may overlap the first semiconductor chip LC in a vertical direction (a Z direction). The first semiconductor chip LC may be a logic chip, and the second semiconductor chip SC may be a sensor chip.

The first semiconductor chip LC may include a logic area LA including logic devices and a peripheral circuit area PE including peripheral circuits. The logic area LA may be surrounded by the peripheral circuit area PE.

The second semiconductor chip SC may be stacked on the first semiconductor chip LC and overlap the first semiconductor chip LC in the vertical direction (the Z direction). The second semiconductor chip SC may include a sensor array area SA, a pad area PA surrounding the sensor array area SA, and a plurality of through via areas TVA between the sensor array area SA and the pad area PA. In the second semiconductor chip SC, the plurality of through via areas TVA and the pad area PA may constitute a peripheral circuit area of the second semiconductor chip SC.

In the second semiconductor chip SC, the sensor array area SA may include an active pixel sensor area APS and an optical black sensor area OBS. The active pixel sensor area APS may include an active pixel configured to generate active signals corresponding to the wavelengths of external light. The optical black sensor area OBS may include an optical black pixel configured to generate optical black signals by blocking external light. A dummy pixel sensor may be an edge portion of the active pixel sensor area APS, which is adjacent to the optical black sensor area OBS.

A plurality of pads 2 may be arranged in the pad area PA of the second semiconductor chip SC. In one or more embodiments, the plurality of pads 2 may transmit and receive electrical signals to and from an external device. In one or more embodiments, the plurality of pads 2 may transmit driving power (e.g., an external power supply voltage or a ground voltage) to internal circuits of the second semiconductor chip SC.

The plurality of through via areas TVA formed in the second semiconductor chip SC may include a plurality of through vias 4. Some of the through vias 4 may be connected to unit pixels in the sensor array area SA through wirings included in the second semiconductor chip SC. Some of the through vias 4 may connect wirings included in the first semiconductor chip LC to the wirings included in the second semiconductor chip SC. Some of the through vias 4 may connect the wirings included in the first semiconductor chip LC to logic devices of the logic area LA included in the second semiconductor chip SC.

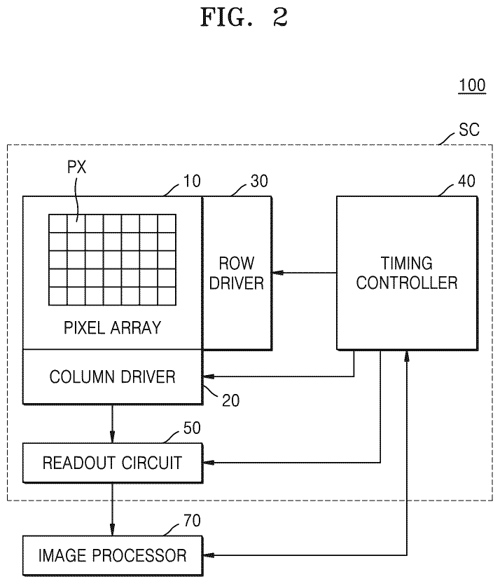

FIG. 2 is a block diagram illustrating components of an image sensor 100 according to one or more example embodiments.

Referring to FIGS. 1 and 2, the image sensor 100 may include a pixel array located in a sensor array area SA and circuits configured to control the pixel array 10. In one or more embodiments, the circuits configured to control the pixel array 10 may include a column driver 20, a row driver 30, a timing controller 40, and a readout circuit 50.

The image sensor 100 may operate in response to a control command received from an image processor 70. The image sensor 100 may convert light transmitted from an external object into an electrical signal and output the electrical signal to the image processor 70. The image sensor 100 may be a complementary metal-oxide-semiconductor (CMOS) image sensor.

The pixel array 10 may include a plurality of unit pixels PX having a two-dimensional (2D) array structure arranged in a matrix form along a plurality of row lines and a plurality of column lines. As used herein, a ‘unit pixel’ may be referred to as a pixel.

Each of the plurality of unit pixels PX may include a photodiode. The photodiode may generate electric charges in response to light received from the object. The image sensor 100 may perform an autofocus function using a phase difference between pixel signals generated from a plurality of photodiodes included in the plurality of unit pixels PX. Each of the unit pixels PX may include a pixel circuit configured to generate a pixel signal from the electric charges generated by the photodiode.

In one or more embodiments, the image sensor 100 may include an image sensor capable of operating as a global shutter. For example, during operations of the image sensor 100, all the unit pixels PX included in the pixel array 10 may be simultaneously exposed to an optical signal provided from the outside, and thus, electric charges may be simultaneously stored in the plurality of unit pixels PX. In one or more embodiments, pixel signals generated due to the electric charges stored in each of the plurality of unit pixels PX may be sequentially output from each row.

The column driver 20 may include a correlated double sampler (CDS) and an analog-digital converter (ADC). The CDS may be connected, through column lines, to a unit pixel PX included in a row selected by a row selection signal supplied by the row driver 30 and perform correlated double sampling to detect a reset voltage and a pixel voltage. The ADC may convert the reset voltage and the pixel voltage each detected by the CDS into digital signals and transmit the digital signals to the readout circuit 50.

The readout circuit 50 may include a latch or a buffer circuit, which may temporarily store the digital signal, and an amplification circuit. The readout circuit 50 may generate image data by temporarily storing or amplifying the digital signal received from the column driver 20. The operation timing of the column driver 20, the row driver 30, and the readout circuit 50 may be determined by the timing controller 40, and the timing controller 40 may operate based on a control command transmitted from the image processor 70.

The image processor 70 may signal-process image data output from the readout circuit 50 and output the signal-processed image data to a display device or store the signal-processed image data in a storage device, such as a memory. When the image sensor 100 is mounted on an autonomous vehicle, the image processor 70 may signal-process image data and transmit the signal-processed image data to a main controller that controls the autonomous vehicle.

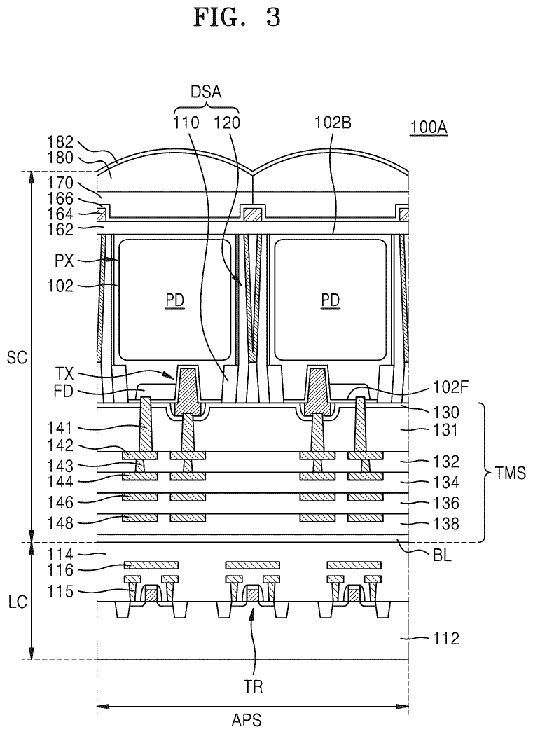

FIG. 3 is a cross-sectional view illustrating a partial region of an image sensor 100A according to one or more example embodiments. FIG. 3 illustrates some components of the active pixel sensor area APS of the sensor array area SA, which may be in the second semiconductor chip SC of the image sensor 100 shown in FIG. 1, and some components of a portion of a first semiconductor chip LC, which overlaps the active pixel sensor area APS in a vertical direction (Z direction).

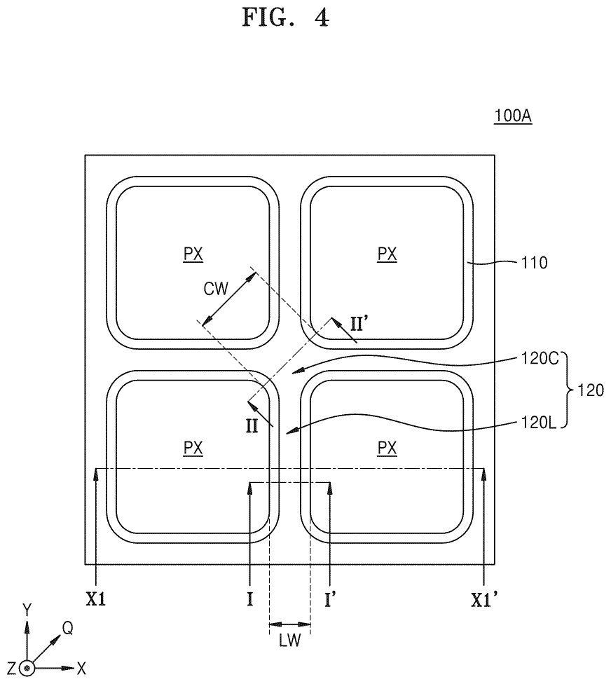

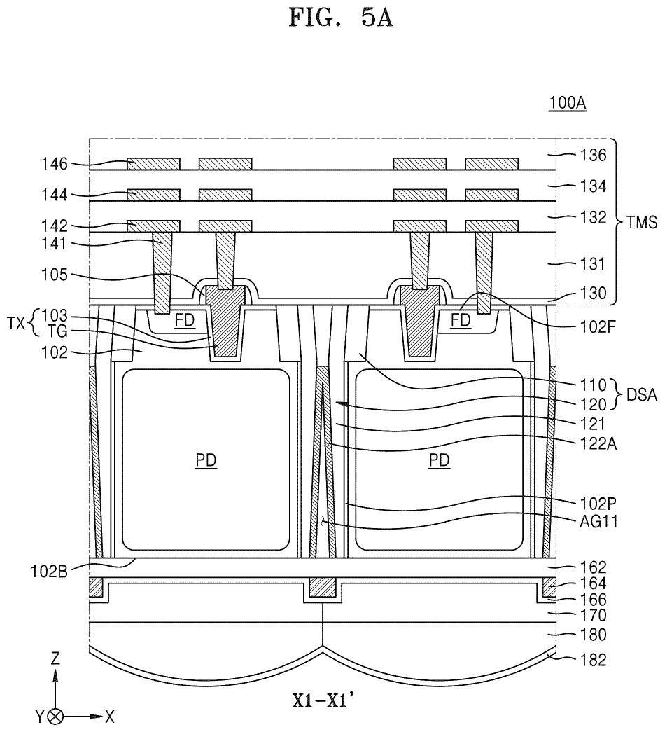

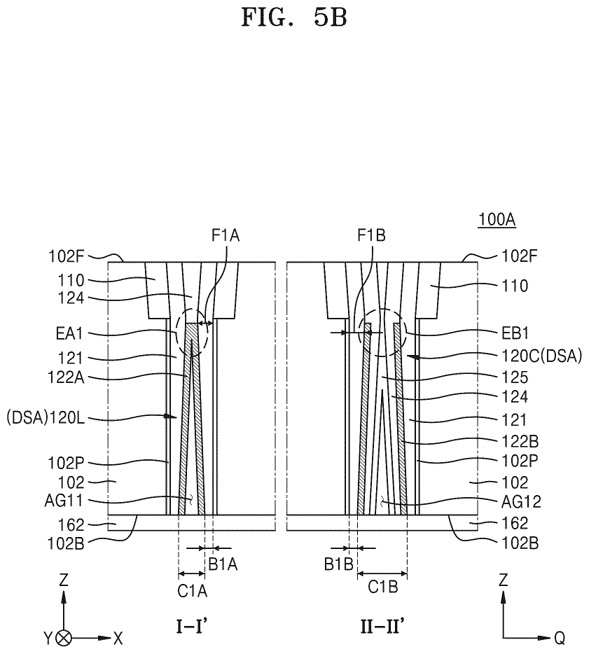

FIG. 4 is a plan view illustrating a pixel isolation structure included in an image sensor according to one or more example embodiments. That is, FIG. 4 is a plan view of a pixel isolation structure DSA defining each of a plurality of unit pixels PX arranged on a substrate 102 in the image sensor 100A. FIG. 5A is an enlarged cross-sectional view illustrating a partial region of a semiconductor chip included in an image sensor according to one or more example embodiments. FIG. 5A illustrates a cross-sectional configuration of some components in a portion corresponding to a cross-section taken along line X1-X1′ of FIG. 4. FIG. 5B is an enlarged cross-sectional view of partial regions of FIG. 5A. FIG. 5B is an enlarged cross-sectional view illustrating partial regions of FIG. 5A according to one or more example embodiments. FIG. 5B illustrates some components in cross-sections taken along lines I-I′ and II-II′ of FIG. 4. Exemplary structures of the image sensor 100A described with reference to FIGS. 3 to 5B may form a portion of the image sensor 100 shown in FIGS. 1 and 2.

Referring to FIGS. 3 to 5B, in the image sensor 100A, the first semiconductor chip LC and the second semiconductor chip SC may be bonded to each other using the bonding layer BL. The plurality of unit pixels PX configured to generate active signals corresponding to the wavelengths of external light may be in an active pixel sensor area APS of the second semiconductor chip SC.

The image sensor 100A may include a substrate 102. The substrate 102 may include a semiconductor layer. In one or more embodiments, the substrate 102 may include a semiconductor layer doped with P-type impurities. For example, the substrate 102 may include a semiconductor layer, which includes silicon (Si), germanium (Ge), silicon germanium (SiGe), a Group II-VI compound semiconductor, a Group III-V compound semiconductor, or a combination thereof. In one or more embodiments, the substrate 102 may include a P-type epitaxial semiconductor layer, which is epitaxially grown from a P-type bulk silicon substrate. The substrate 102 may have a frontside surface 102F and a backside surface 102B, which are opposite to each other.

Each of the plurality of unit pixels PX may include a photodiode PD, a floating diffusion region FD, and a transfer transistor TX. The photodiode PD and the floating diffusion region FD may be in the substrate 102. The photodiode PD may generate electric charges in proportion to the amount of light incident from the outside. The generated electric charges may be accumulated in the photodiode PD, and the electric charges accumulated in the photodiode PD may be transmitted to the floating diffusion region FD. The electric charges transmitted to the floating diffusion region FD may be applied to a source follower gate of the unit pixel PX. One end of the transfer transistor TX may be connected to the photodiode PD, and another end of the transfer transistor TX may be connected to the floating diffusion region FD. The transfer transistor TX may transmit the electric charges generated by the photodiode PD to the floating diffusion region FD.

As shown in FIG. 5A, the transfer transistor TX may include a transfer gate TG and a gate insulating film 103. Sidewalls of the transfer gate TG may be covered by insulating spacers 105. The transfer gate TG may include a portion buried in the substrate 102. The gate insulating film 103 may be between the transfer gate TG and the substrate 102.

As shown in FIGS. 4 and 5A, the pixel isolation structure DSA may include a local device isolation film 110 and a main device isolation film 120. The main device isolation film 120 may refer to a combination of components, such as components 121, 122A, AG11, etc., to be described later. The main device isolation film 120 may extend through the substrate 102 from the frontside surface 102F of the substrate 102 to the backside surface 102B thereof in a vertical direction (Z direction) to define the plurality of unit pixels PX. The local device isolation film 110 may extend through only a portion of the substrate 102 from the frontside surface 102F of the substrate 102 in the vertical direction (Z direction) and cover a partial sidewall of the main device isolation film 120. As used herein, the vertical direction (Z direction) may refer to a direction perpendicular to the backside surface 102B of the substrate 102. In one or more embodiments, the local device isolation film 110 may include a silicon oxide film.

As shown in FIG. 4, in the image sensor 100A, the pixel isolation structure DSA may have a network-type planar structure. The main device isolation film 120 of the pixel isolation structure DSA may include a line isolation portion 120L and a corner isolation portion 120C. The line isolation portion 120L may linearly extend along a side of each of two adjacent unit pixels PX of the unit pixels PX and between the two adjacent unit pixels PX. The corner isolation portion 120C may contact a corner of each of at least two (e.g., four) adjacent unit pixels PX of the unit pixels PX. The corner isolation portion 120C may be in a portion where a plurality of line isolation portions 120L meet each other. As shown in FIG. 4, the main device isolation film 120 of the pixel isolation structure DSA may have a network-type planar structure.

The line isolation portion 120L may have a first width LW in a direction (e.g., an X direction or a Y direction of FIG. 4) in which two unit pixels PX face each other with the line isolation portion 120L therebetween. Between two unit pixels PX, which face each other in a diagonal direction (e.g., a Q direction in FIG. 4) with the corner isolation portion 120C therebetween, the corner isolation portion 120C may have a second width CW in the diagonal direction. The second width CW may be greater than the first width LW.

As shown in FIG. 5B, the line isolation portion 120L of the pixel isolation structure DSA may include a first insulating pattern 121, a first conductive pattern 122A, a first air gap AG11, and a second insulating pattern 124. As used herein, the term “air” may refer to the atmosphere, other gases that may be during a manufacturing process, or a space including solids obtained from reaction resultants of the gases. As used herein, an air gap may be referred to as a space.

In the line isolation portion 120L of the pixel isolation structure DSA, the first conductive pattern 122A may be surrounded by the first air gap AG11. The first conductive pattern 122A may be exposed at the first air gap AG11, and a size of the first air gap AG11 in a lateral direction (or X direction in FIG. 5B) may be defined by the first conductive pattern 122A). That is, the first conductive pattern 122A may surround the first air gap AG11 in the line isolation portion 120L of the pixel isolation structure DSA, such that one side of the first conductive pattern 122A is exposed to the first air gap AG11 and another side of the first conductive pattern 122A is not exposed to the first air gap AG11. The first insulating pattern 121 may surround the first air gap AG11 and the first conductive pattern 122A. In the line isolation portion 120L, the first insulating pattern 121 may have an inner surface contacting the first conductive pattern 122A and an outer surface contacting the local device isolation film 110.

In the line isolation portion 120L, the second insulating pattern 124 may overlap the first conductive pattern 122A and the first air gap AG11 in the vertical direction (Z direction). The second insulating pattern 124 may include a bottom surface contacting the first conductive pattern 122A and a side surface that faces the local device isolation film 110 with the first insulating pattern 121 therebetween in the lateral direction (or X direction in FIG. 5B).

The corner isolation portion 120C of the pixel isolation structure DSA may include a first insulating pattern 121, a second conductive pattern 122B, a second insulating pattern 124, a third insulating pattern 125, and a second air gap AG12. The first insulating pattern 121 of the corner isolation portion 120C may be integrally connected to the first insulating pattern 121 of the line isolation portion 120L. In the corner isolation portion 120C, the first insulating pattern 121 may have an inner surface contacting the second conductive pattern 122B and an outer surface contacting the local device isolation film 110. The second conductive pattern 122B of the corner isolation portion 120C may be integrally connected to the first conductive pattern 122A of the line isolation portion 120L. The second insulating pattern 124 of the corner isolation portion 120C may be integrally connected to the second insulating pattern 124 of the line isolation portion 120L. The third insulating pattern 125 of the corner isolation portion 120C may be at the center of the corner isolation portion 120C. The third insulating pattern 125 of the corner isolation portion 120C may be exposed at the second air gap AG12, and a size of the second air gap AG12 in the lateral direction (or X direction in FIG. 5B) may be defined by the third insulating pattern 125. That is, the third insulating pattern 125 may have an inner surface that is exposed to the second air gap AG12. The third insulating pattern 125 of the corner isolation portion 120C may include a portion that faces the local device isolation film 110 with the first insulating pattern 121 and the second insulating pattern 124 therebetween. In a portion adjacent to the backside surface 102B of the substrate 102, the first insulating pattern 121 of the corner isolation portion 120C may surround the second conductive pattern 122B, the second insulating pattern 124, the third insulating pattern 125, and the second air gap AG12. In the corner isolation portion 120C, the second insulating pattern 124 and the third insulating pattern 125 may constitute an inner insulating structure surrounded by the second conductive pattern 122B. The inner insulating structure may include a portion contacting the second conductive pattern 122B and a portion that faces the local device isolation film 110 with the first insulating pattern 121 therebetween in the lateral direction (or X direction in FIG. 5B).

As shown in FIG. 5B, in the pixel isolation structure DSA, each of the first insulating pattern 121 of the line isolation portion 120L and the first insulating pattern 121 of the corner isolation portion 120C may have a tapered cross-sectional shape with a width in the lateral direction (or X direction in FIG. 5B) gradually increasing from the backside surface 102B of the substrate 102 toward the frontside surface 102F of the substrate 102. In the lateral direction (e.g., X direction in FIG. 5B) of the first insulating pattern 121 of the line isolation portion 120L, a width F1A of a portion that is adjacent to the frontside surface 102F of the substrate 102 and covers the first conductive pattern 122A, may be greater than a width B1A of a portion that is adjacent to the backside surface 102B of the substrate 102 and covers the first conductive pattern 122A. In the lateral direction (or X direction in FIG. 5B) of the first insulating pattern 121 of the corner isolation portion 120C, a width F1B of a portion that is adjacent to the frontside surface 102F of the substrate 102 and covers the second conductive pattern 122B may be greater than a width B1B of a portion that is adjacent to the backside surface 102B of the substrate 102 and covers the second conductive pattern 122B.

In the lateral direction (or X direction in FIG. 5B), a maximum width C1A of the first conductive pattern 122A included in the line isolation portion 120L may be less than a maximum width C1B of the second conductive pattern 122B included in the corner isolation portion 120C. A width of each of the first conductive pattern 122A and the second conductive pattern 122B in the lateral direction (or X direction in FIG. 5B) may vary along the vertical direction (Z direction). For example, in the pixel isolation structure DSA, each of the first conductive pattern 122A and the second conductive pattern 122B may have a tapered cross-sectional shape with a width in the lateral direction (or X direction in FIG. 5B) gradually increasing from the frontside surface 102F of the substrate 102 toward the backside surface 102B of the substrate 102. Accordingly, each of the first conductive pattern 122A and the second conductive pattern 122B may include a tapered surface, which faces the photodiode PD and is inclined with respect to the backside surface 102B of the substrate 102.

Each of the first conductive pattern 122A and the second conductive pattern 122B may have a width in the lateral direction (or X direction in FIG. 5B) gradually decreasing toward the local device isolation film 110 in the vertical direction (Z direction). Each of the first conductive pattern 122A and the second conductive pattern 122B may include a pair of inclined patterns inclined in mutually opposite directions with respect to the vertical direction (Z direction). That is, the left pattern of the pair of inclined patterns may be inclined at an opposite direction with respect to the vertical direction as opposed to the right pattern of the pair of inclined patterns. As shown in a dashed area EA1 of FIG. 5B, the pair of inclined patterns of the first conductive pattern 122A may contact each other at a position closest to the local device isolation film 110. The position closes to the local device isolation film 110 (or closest to another component) may refer to a position where a portion of each of the pair of inclined patterns of the first conductive pattern 122A is most proximate to the local device isolation film 110, and may include a range of the portion of each of the pair of inclined patterns of the first conductive pattern 122A that are most proximate to the local device isolation film 110. As shown in a dashed area EB1 of FIG. 5B, the pair of inclined patterns of the second conductive pattern 122B may be spaced apart from each other at a position closest to the local device isolation film 110.

In one or more embodiments, each of the first conductive pattern 122A and the second conductive pattern 122B may include polysilicon doped with P-type impurities or polysilicon doped with N-type impurities. For example, each of the first conductive pattern 122A and the second conductive pattern 122B may include polysilicon doped with boron (B) or phosphorus (P), without being limited thereto.

A doped isolation liner 102P may be between the substrate 102 and the main device isolation film 120. In the line isolation portion 120L and the corner isolation portion 120C, the first insulating pattern 121 may be in contact with the doped isolation liner 102P. The doped isolation liner 102P may include a silicon region doped with P+-type impurities. For example, the doped isolation liner 102P may include a silicon region doped with boron (B) ions, without being limited thereto. The doped isolation liner 102P may improve the quality of the image sensor 100A by reducing a dark current in the unit pixel PX. The doped isolation liner 102P may reduce a dark current generated by electron-hole pairs that occur due to surface defects between the main device isolation film 120 and the doped isolation liner 102P.

As shown in FIG. 5A, an etch stop film 130 covering the transfer gate TG may be on the frontside surface 102F of the substrate 102. The etch stop film 130 may conformally cover the transfer gate TG, the insulating spacers 105, the floating diffusion region FD, and the pixel isolation structure DSA. The etch stop film 130 may include silicon nitride, silicon oxynitride, or a combination thereof, without being limited thereto.

As shown in FIG. 5A, the image sensor 100A may include a backside insulating film 162 covering the backside surface 102B of the substrate 102 and a plurality of grid patterns 164, a plurality of color filters 170, and a plurality of microlenses 180, which are on the backside insulating film 162.

In some embodiments, the backside insulating film 162 may include a silicon oxide film, a silicon nitride film, a silicon oxynitride film, an aluminum oxide film, a hafnium oxide film, or a combination thereof, without being limited thereto. The backside insulating film 162 may serve as an anti-reflective film. The backside insulating film 162 may improve a light reception rate of the photodiode PD by preventing reflection of light incident on the substrate 102 from the outside. The backside insulating film 162 may have a flattened surface. The plurality of color filters 170 and the plurality of microlenses 180 may be arranged on the flattened surface of the backside insulating film 162, and thus, respective heights of the plurality of color filters 170 and the plurality of microlenses 180 may be made uniform.

The plurality of color filters 170 may be arranged to correspond to the unit pixels PX on the backside insulating film 162. The plurality of color filters 170 may include various color filters depending on the unit pixel PX. In some embodiments, the plurality of color filters 170 may be arranged in a Bayer pattern including a red color filter, a green color filter, and a blue color filter. In some embodiments, the plurality of color filters 170 may include a yellow filter, a magenta filter, and a cyan filter and may further include a white filter.

The grid pattern 164 may include a material having a lower refractive index than silicon (Si). In some embodiments, the grid pattern 164 may include a silicon oxide film, aluminum oxide film, a tantalum oxide film, or a combination thereof, without being limited thereto.

A first protective film 166 may be between the backside insulating film 162 and the plurality of color filters 170 and between the plurality of grid patterns 164 and the plurality of color filters 170. The first protective film 166 may conformally cover a top surface of the backside insulating film 150 and a side surface and a top surface of the grid pattern 164. The first protective film 166 may prevent the backside insulating film 162 and the grid pattern 164 from being damaged. The first protective film 166 may include an aluminum oxide film, without being limited thereto.

A second protective film 182 may be formed on the microlens 180. The second protective film 182 may conformally cover a surface of the microlens 180. The second protective film 182 may protect the microlens 180 from external shocks and improve light-condensing capability of the microlens 180. In some embodiments, the second protective film 182 may include a silicon oxide film, a titanium oxide film, a zirconium oxide film, a hafnium oxide film, or a combination thereof, without being limited thereto.

A wiring structure TMS may be on the frontside surface 102F of the substrate 102. The wiring structure TMS may include a plurality of interlayer insulating films (e.g., 131, 132, 134, 136, and 138) covering a plurality of transfer transistors TX, a plurality of via contacts (e.g., 141 and 143) and a plurality of wiring layers (e.g., 142, 144, 146, and 148), which are covered by the interlayer insulating films 131, 132, 134, 136, and 138, and a bonding layer BL. Some of the via contacts 141 and 143 may electrically connect the floating diffusion region FD to the wiring layers 142, 144, 146, and 148. The stacked numbers and arrangements of the interlayer insulating films 131, 132, 134, 136, and 138 and the wiring layers 142, 144, 146, and 148 are not limited to those illustrated in FIG. 3 and may be variously changed and modified as needed. The wiring layers 142, 144, 146, and 148 may include conductive lines connected to a plurality of transistors, which are electrically connected to the photodiode PD. An electrical signal converted by the photodiode PD may be signal-processed through the wiring layers 142, 144, 146, and 148. In some embodiments, the interlayer insulating films 131, 132, 134, 136, and 138 may include a silicon oxide film, a silicon nitride film, a silicon oxynitride film, a low-k dielectric film having a lower dielectric constant than the silicon oxide film, or a combination thereof, without being limited thereto. In some embodiments, each of the via contacts 141 and 143 and the wiring layers 142, 144, 146, and 148 may include tungsten (W), copper (Cu), aluminum (Al), gold (Au), silver (Ag), or a combination thereof, without being limited thereto.

As shown in FIG. 3, the first semiconductor chip LC may include a logic substrate 112 and a plurality of transistors TR on the logic substrate 112. The plurality of transistors TR may constitute a logic circuit. In some embodiments, the plurality of transistors TR may constitute a circuit configured to control transistors included in the second semiconductor chip SC.

An interlayer insulating film 114 covering the plurality of transistors TR and a plurality of via contacts 115 and a plurality of wiring layers 116, which are covered by the interlayer insulating film 114, may be on the logic substrate 112. The plurality of transistors TR may be electrically connected to the plurality of wiring layers 116 through the plurality of via contacts 115. The interlayer insulating film 114 may include a silicon oxide film, a silicon nitride film, a silicon oxynitride film, a low-k dielectric film having a lower dielectric constant than the silicon oxide film, or a combination thereof, without being limited thereto. The plurality of via contacts 115 and the plurality of wiring layers 116 may each include tungsten (W), copper (Cu), aluminum (Al), gold (Au), silver (Ag), or a combination thereof, without being limited thereto.

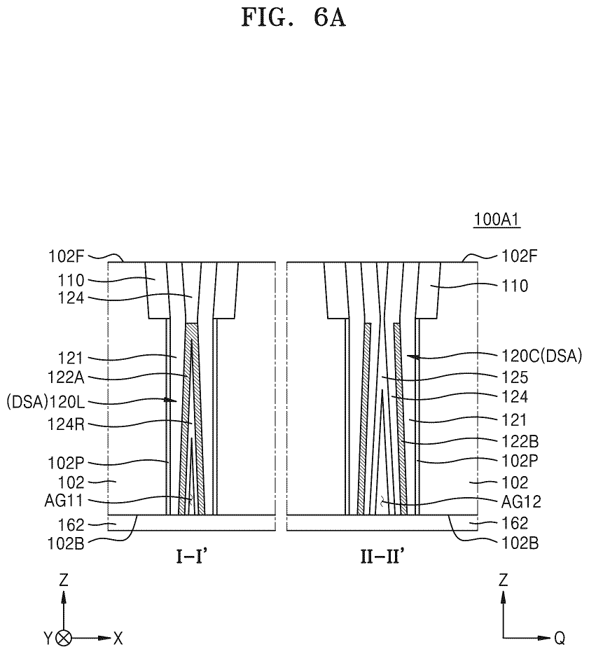

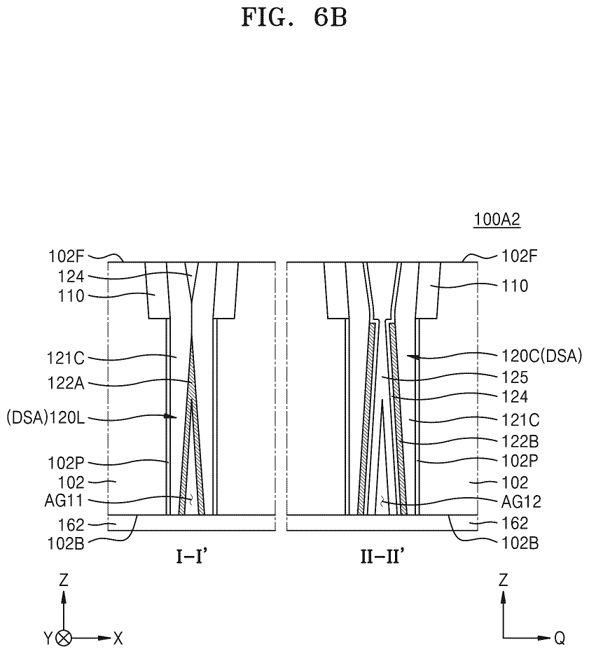

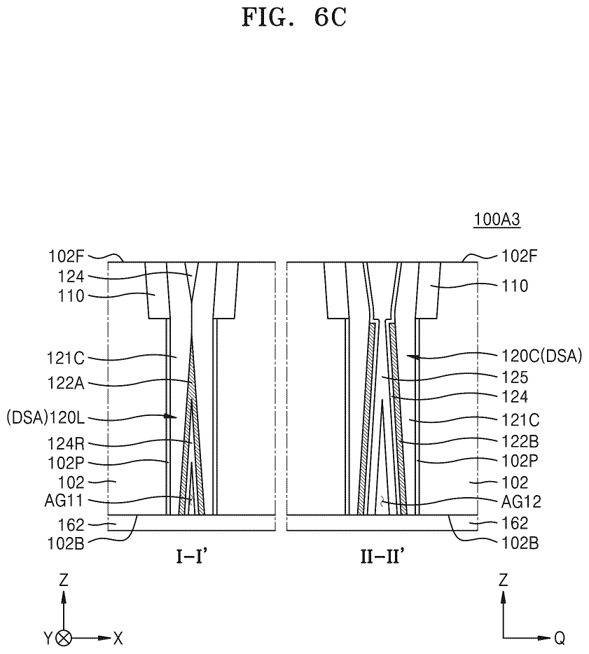

FIGS. 6A to 6C are cross-sectional views illustrating image sensors according to one or more example embodiments. FIGS. 6A to 6C each illustrate an enlarged cross-sectional configuration of portions of the corresponding one of the image sensors 100A1, 100A2, and 100A3, which correspond to partial regions of FIG. 5A. In FIGS. 6A to 6C, the same reference numerals are used to denote the same elements as in FIGS. 1 to 5C, and detailed descriptions thereof are omitted here.

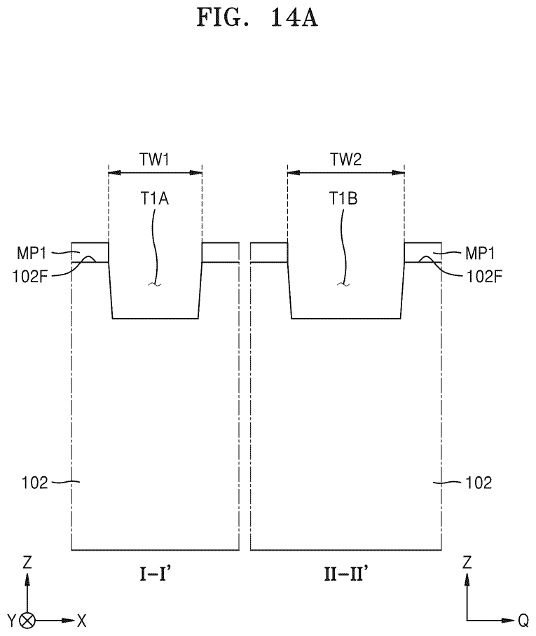

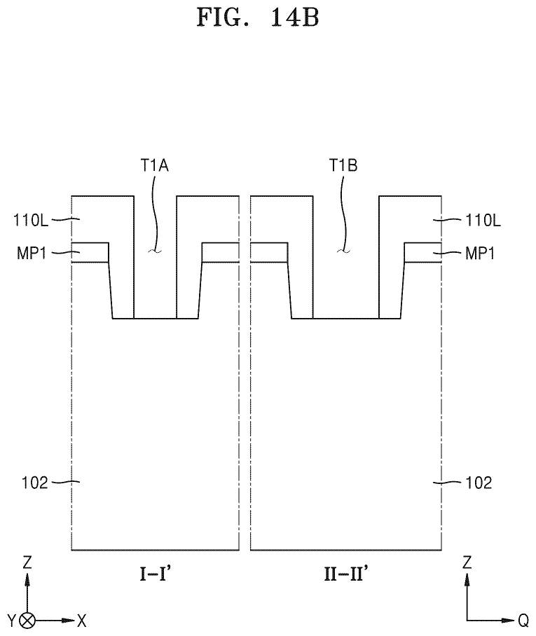

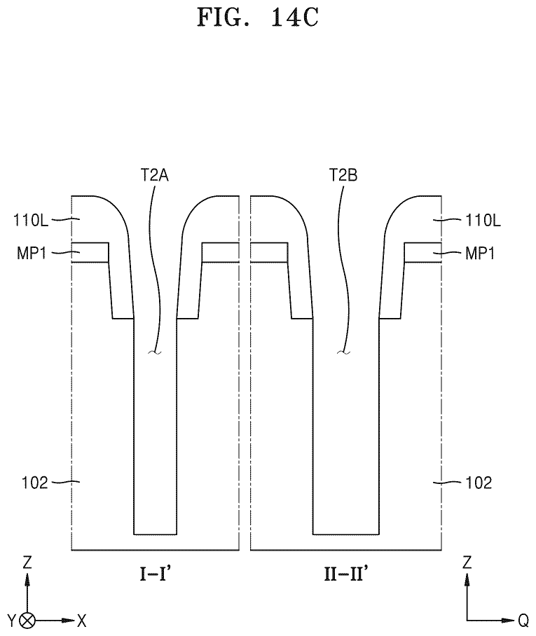

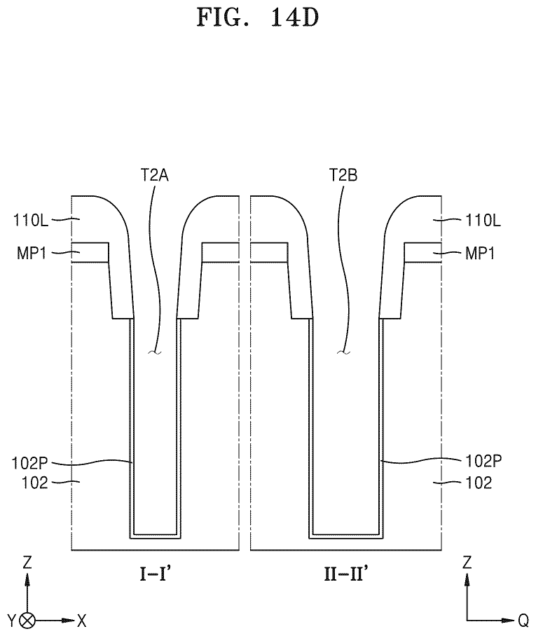

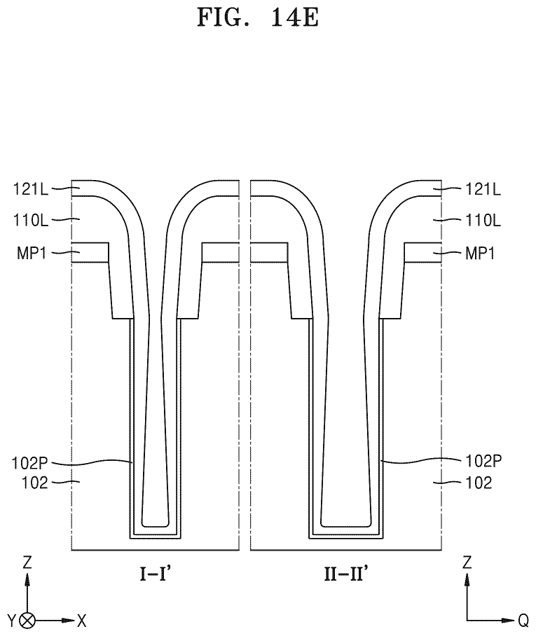

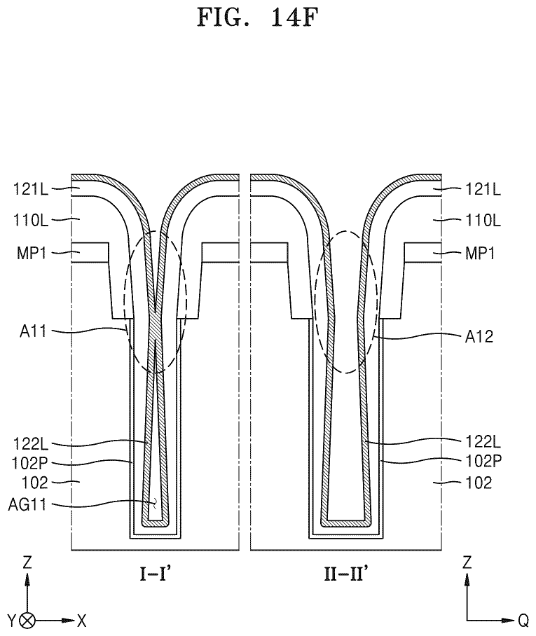

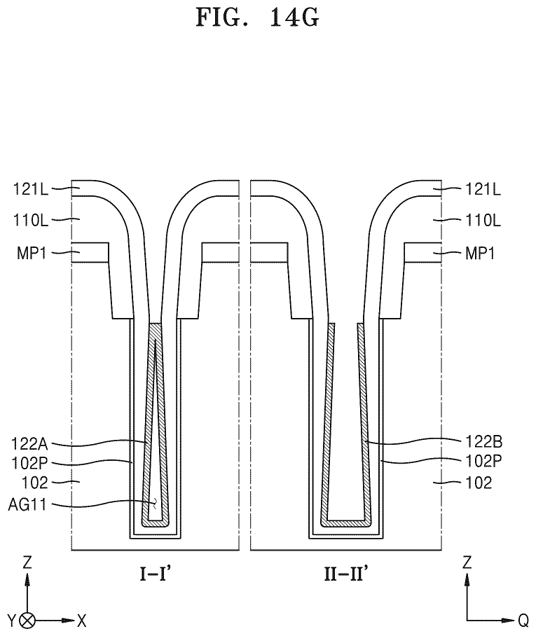

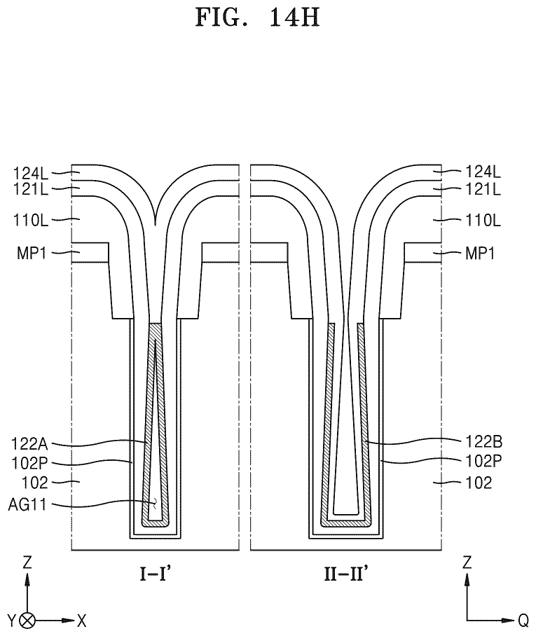

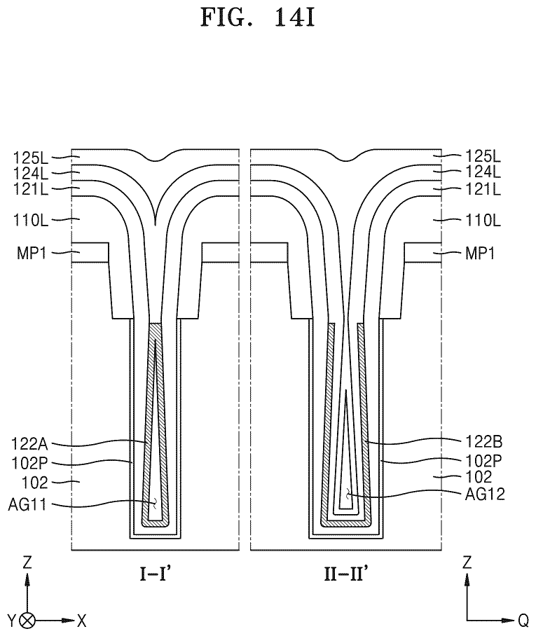

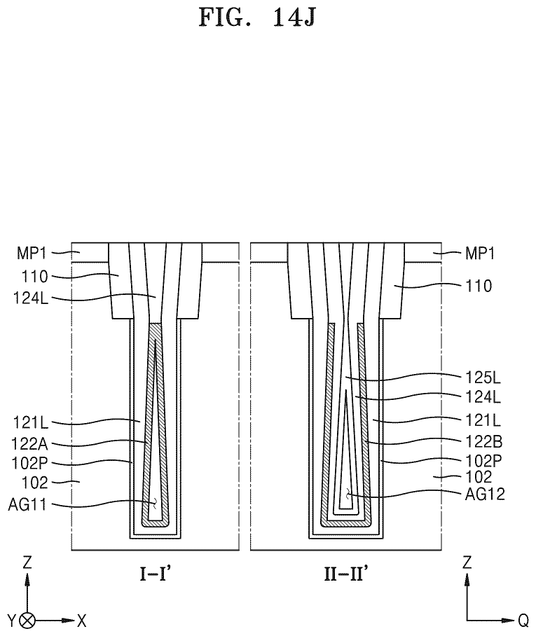

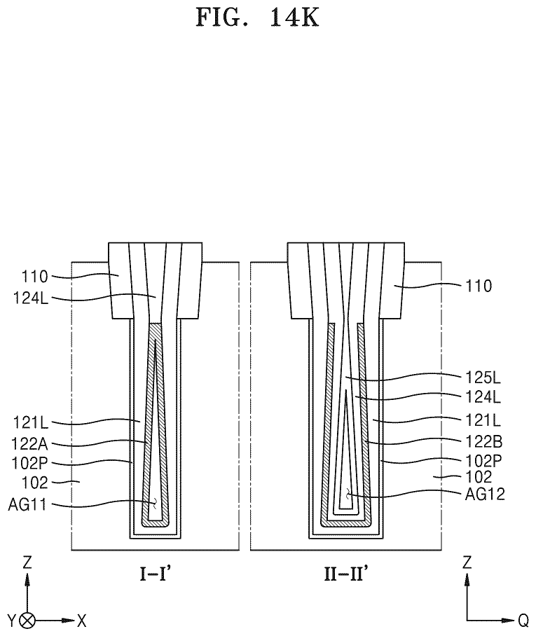

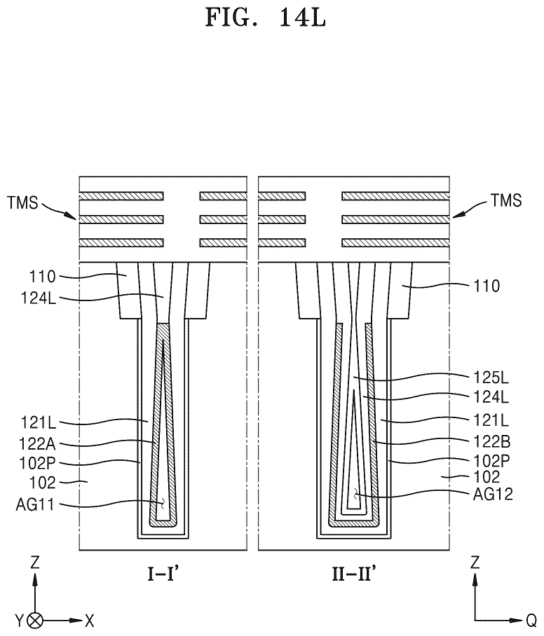

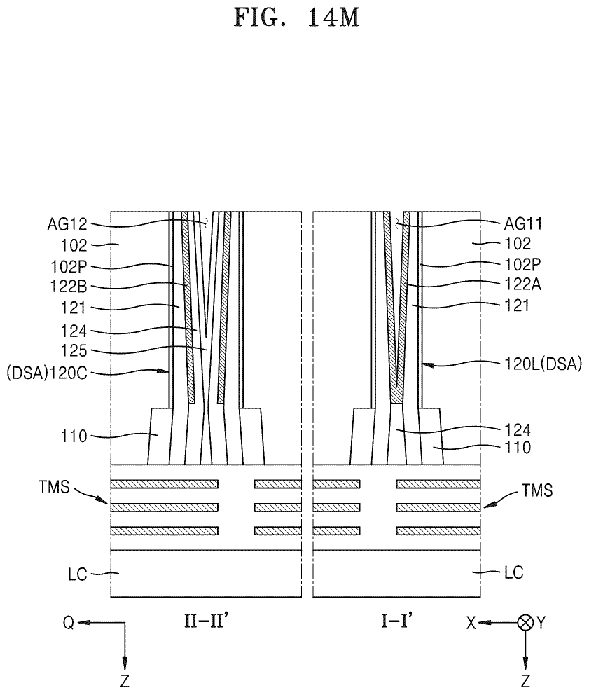

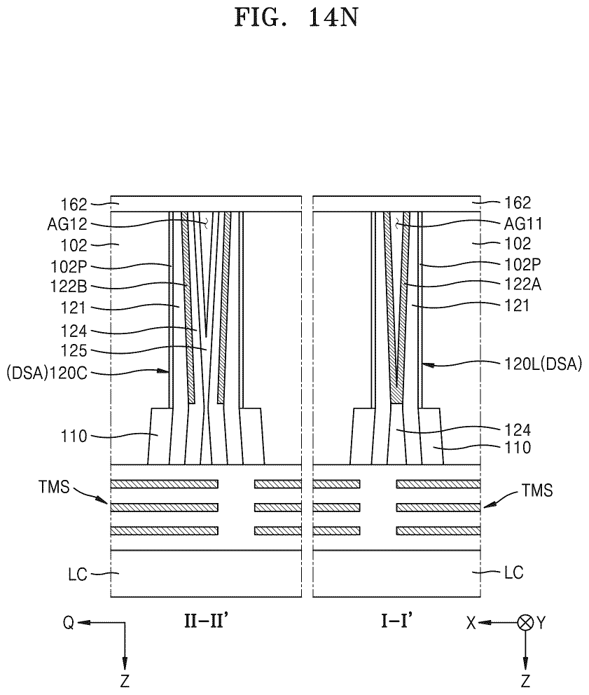

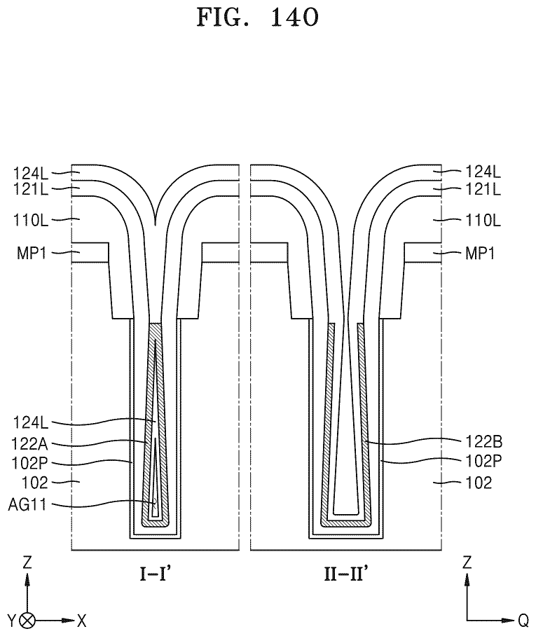

Referring to FIG. 6A, the image sensor 100A1 may substantially have the same configuration as the image sensor 100A described with reference to FIGS. 3 to 5B. However, in the image sensor 100A1, a line isolation portion 120L of a main device isolation film 120 may further include an inner insulating film 124R between a first conductive pattern 122A and a first air gap AG11. In the line isolation portion 120L, the inner insulating film 124R may constitute an inner insulating structure surrounded by the first conductive pattern 122A. The inner insulating film 124R may include the same material as the second insulating pattern 124. In one or more embodiments, during the formation of the second insulating pattern 124 (e.g. the process described with reference to FIG. 14H), reactants required to form a second insulating film 124L for forming the second insulating pattern 124 may move to a deep trench T2A through a deep trench T2B. Accordingly, as shown in FIG. 14O, a portion of the second insulating film 124L may be formed also inside the first air gap AG11 in a deep trench T2A. The portion of the second insulating film 124L, which is formed inside the first air gap AG11, may be removed by a cleaning process after subsequent processes (e.g., a process described below with reference to FIG. 14M). Alternatively, as described above with reference to FIG. 6A, a portion of the second insulating film 124L, which is formed inside the first air gap AG11, may not be removed but remain as the inner insulating film 124R inside the first air gap AG11.

Referring to FIG. 6B, the image sensor 100A2 may substantially have the same configuration as the image sensor 100A described with reference to FIGS. 3 to 5B. However, the image sensor 100A2 may include a first insulating pattern 121C instead of the first insulating pattern 121.

A thickness of the first insulating pattern 121C may be greater than that of the first insulating pattern 121 shown in FIG. 5B at entrances of deep trenches T2A and T2B (i.e., at boundaries between shallow trenches T1A and T1B and the deep trenches T2A and T2B). An entrance of the deep trench T2A, which is boundary between the shallow trench T1A and the deep trench T2A, may be blocked by the first insulating pattern 121C, and a first conductive pattern 122A and a first air gap AG11 defined by the first conductive pattern 122A may be located in a space defined by the first insulating pattern 121C inside the deep trench T2A.

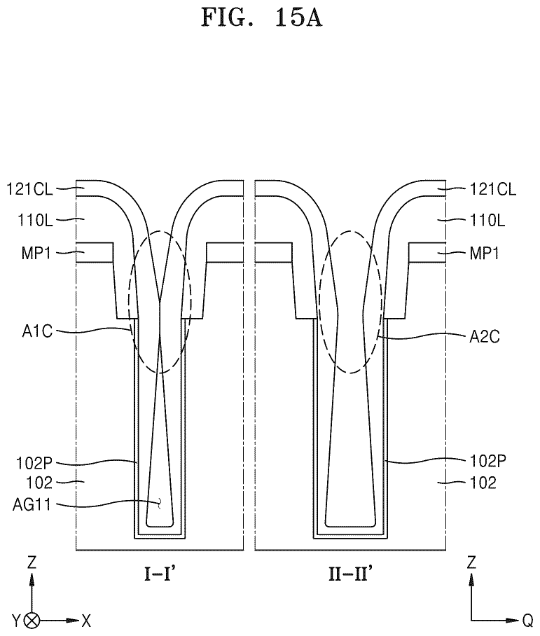

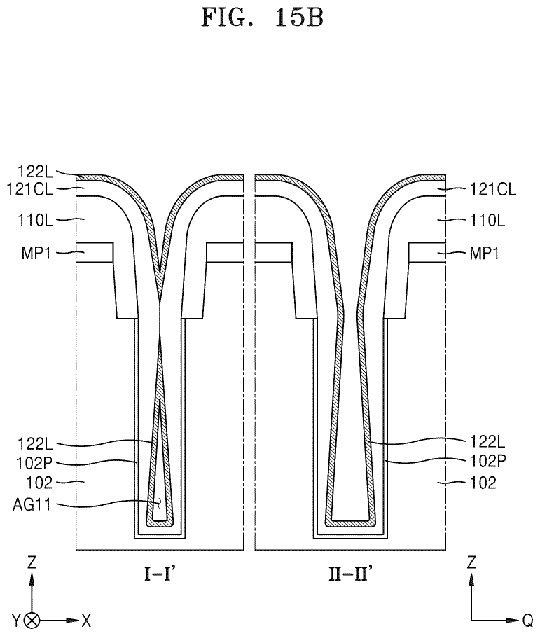

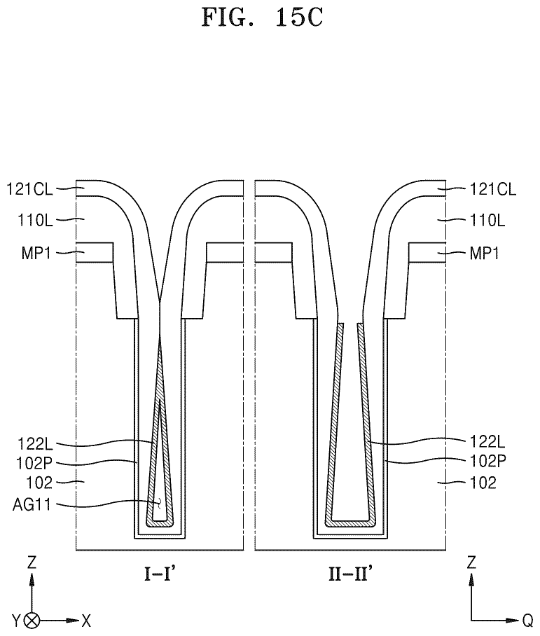

In one or more embodiments, the first insulating pattern 121C may be obtained from a first insulating film 121CL formed using the process described with reference to FIG. 15A.

Referring to FIG. 6C, the image sensor 100A3 may substantially have the same configuration as the image sensor 100A2 described with reference to FIG. 6B. However, in the image sensor 100A3, a line isolation portion 120L of a main device isolation film 120 may further include an inner insulating film 124R between a first conductive pattern 122A and a first air gap AG11. A detailed configuration of the inner insulating film 124R is the same as that described with reference to FIG. 6A.

Exemplary structures of the image sensors 100A, 100A1, 100A2, and 100A3 described with reference to FIGS. 3, 4, 5A, 5B, 6A, 6B, and 6C may each constitute a portion of the image sensor 100 shown in FIGS. 1 and 2. The image sensors 100A, 100A1, 100A2, and 100A3 described with reference to FIGS. 3, 4, 5A, 5B, 6A, 6B, and 6C may include the pixel isolation structure DSA, which extends through the substrate 102 in the vertical direction (Z direction) to define a plurality of unit pixels PX and have network-type planar structures. Accordingly, issues, such as shift, collapse, deformation, etc., of the pixel isolation structure DSA and peripheral components thereof may be prevented during and/or after the manufacture of the image sensors 100A, 100A1, 100A2, and 100A3. Furthermore, by applying a negative bias to the pixel isolation structure DSA, characteristics (e.g., a dark current and white spots) of each of all the unit pixels PX defined by the pixel isolation structure DSA may be effectively controlled. Accordingly, the sensitivity and resolution of the image sensors 100A, 100A1, 100A2, and 100A3 may be improved.

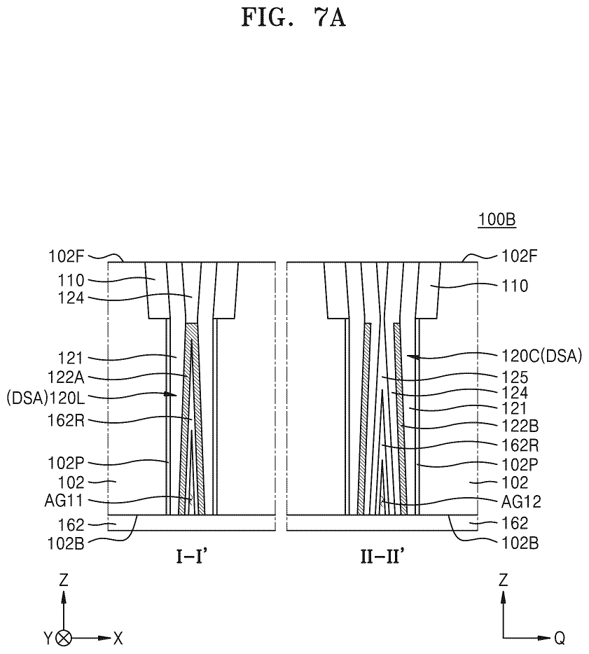

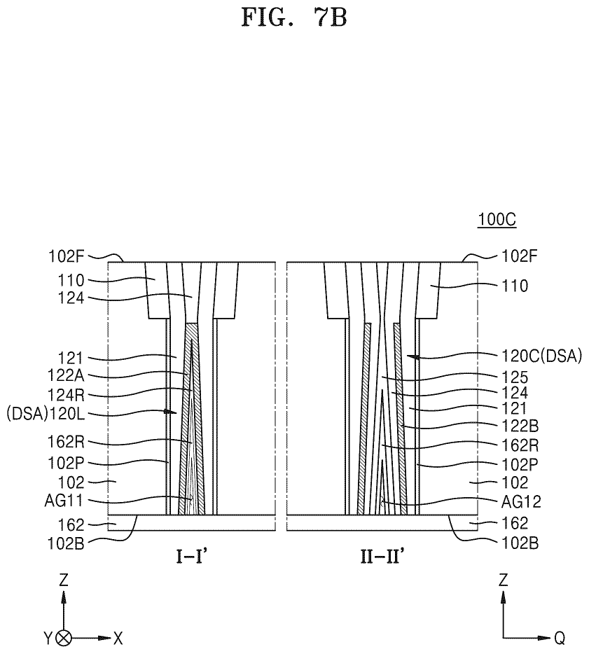

FIGS. 7A and 7B are respectively cross-sectional views of image sensors 100B and 100C according to one or more embodiments. FIGS. 7A and 7B each illustrate an enlarged cross-sectional configuration of portions of the corresponding one of the image sensors 100B and 100C, which correspond to partial regions of FIG. 5A. In FIGS. 7A and 7B, the same reference numerals are used to denote the same elements as in FIGS. 1 to 5B, and detailed descriptions thereof may be omitted here.

Referring to FIG. 7A, the image sensor 100B may substantially have the same configuration as the image sensor 100A described with reference to FIGS. 3 to 5B. However, in the image sensor 100B, a line isolation portion 120L of a main device isolation film 120 may further include an inner insulating film 162R between a first conductive pattern 122A and a first air gap AG11, and a corner isolation portion 120C may further include an inner insulating film 162R between a second conductive pattern 122B and a second air gap AG12. In the line isolation portion 120L, the inner insulating film 162R may constitute an inner insulating structure surrounded by the first conductive pattern 122A. In the corner isolation portion 120C, the second insulating pattern 124, the third insulating pattern 125, and the inner insulating film 162R may constitute an inner insulating structure surrounded by the second conductive pattern 122B.

FIG. 7A illustrates an example in which the inner insulating film 162R has a shape that continuously and conformally covers the first conductive pattern 122A and the second conductive pattern 122B inside the first air gap AG11 and the second air gap AG12, but the disclosure is not limited thereto. For example, the inner insulating film 162R may cover only partial surfaces of the first conductive pattern 122A and the second conductive pattern 122B inside the first air gap AG11 and the second air gap AG12. In this case, the inner insulating film 162R, the first conductive pattern 122A, and a backside insulating film 162 may be exposed together inside the first air gap AG11, and the inner insulating film 162R, the second conductive pattern 122B, and the backside insulating film 162 may be exposed together inside the second air gap AG12.

In one or more embodiments, the inner insulating film 162R may include the same material as a constituent material of the backside insulating film 162. For example, the inner insulating film 162R may include a silicon oxide film, a polysilicon film, a silicon nitride film, a silicon oxynitride film, an aluminum oxide film, a hafnium oxide film, or a combination thereof, without being limited thereto.

Referring to FIG. 7B, the image sensor 100C may substantially have the same configuration as the image sensor 100B described with reference to FIG. 7A. However, in the image sensor 100C, a line isolation portion 120L of a main device isolation film 120 may further include an inner insulating film 124R between a first conductive pattern 122A and an inner insulating film 162R. In the line isolation portion 120L, the inner insulating film 124R and the inner insulating film 162R may constitute an inner insulating structure surrounded by a first conductive pattern 122A. The inner insulating film 124R may include the same material as the second insulating pattern 124. In one or more embodiments, during the formation of the second insulating pattern 124 (e.g., in the process described with reference to FIG. 14H), reactants required to form the second insulating pattern 124 may move to a deep trench T2A through a deep trench T2B. Accordingly, the inner insulating film 124R including the same material as the second insulating pattern 124 may be formed also inside the first air gap AG11 in the deep trench T2A.

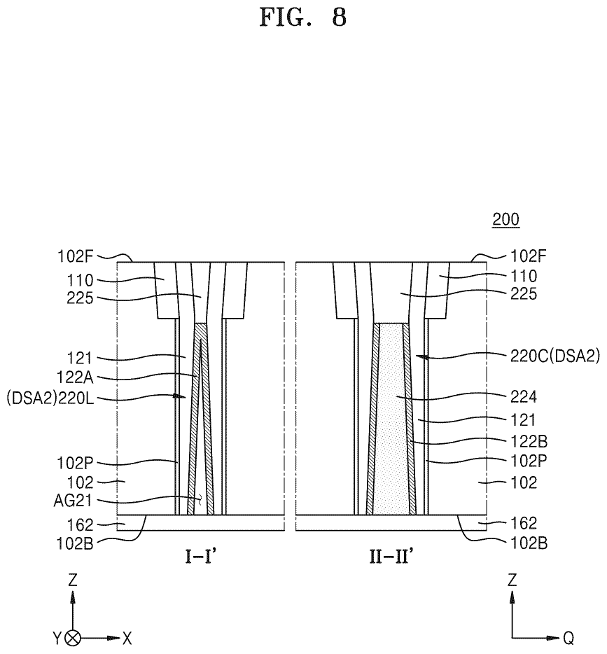

FIGS. 8, 9A, 9B, 9C, 10, 11, 12, and 13 are respectively cross-sectional views of image sensors 200, 200A, 200B, 200C, 300A, 300B, 400A, and 400B according to one or more embodiments. FIGS. 8, 9A, 9B, 10, 11, 12, and 13 each illustrate an enlarged cross-sectional configuration of portions of the corresponding one of the image sensors 200, 200A, 200B, 200C, 300A, 300B, 400A, and 400B, which correspond to partial regions of FIG. 5A. In FIGS. 8 to 13, the same reference numerals are used to denote the same elements as in FIGS. 1 to 7B, and detailed descriptions thereof may be omitted here.

Referring to FIG. 8, the image sensor 200 may substantially have the same configuration as the image sensor 100A described with reference to FIGS. 3 to 5B. However, in the image sensor 200, a line isolation portion 220L of a pixel isolation structure DSA2 may include a first insulating pattern 121, a first conductive pattern 122A, a first air gap AG21, and a second insulating pattern 225. The second insulating pattern 225 may substantially have the same configuration as the second insulating pattern 124 described with reference to FIG. 5B. In the line isolation portion 220L, the second insulating pattern 225 may overlap the first conductive pattern 122A and the first air gap AG21 in a vertical direction (Z direction). The second insulating pattern 225 may include an inner surface contacting the first conductive pattern 122A and an outer surface that faces a local device isolation film 110 with the first insulating pattern 121 therebetween in a lateral direction (or X direction in FIG. 8). A constituent material of the second insulating pattern 225 may substantially be the same as that of the first insulating pattern 121, which is described above with reference to FIG. 5B.

A corner isolation portion 220C of the pixel isolation structure DSA2 may include a first insulating pattern 121, a second conductive pattern 122B, a polysilicon plug 224, and a second insulating pattern 225. The first insulating pattern 121 of the corner isolation portion 220C may be integrally connected to the first insulating pattern 121 of the line isolation portion 220L. In the corner isolation portion 220C, the first insulating pattern 121 may have an inner surface contacting the second conductive pattern 122B and an outer surface contacting the local device isolation film 110. The second insulating pattern 225 of the corner isolation portion 220C may be integrally connected to the second insulating pattern 225 of the line isolation portion 220L. The second insulating pattern 225 of the corner isolation portion 220C may be at the center of the corner isolation portion 220C. The second insulating pattern 225 of the corner isolation portion 220C may overlap the polysilicon plug 224 in the vertical direction (Z direction) and contact each of the polysilicon plug 224 and the second conductive pattern 122B. In the lateral direction (or X direction in FIG. 8), the second insulating pattern 225 of the corner isolation portion 220C may include a portion that faces the local device isolation film 110 with the first insulating pattern 121 therebetween.

The polysilicon plug 224 may be surrounded by the second conductive pattern 122B and fill a space defined by the second conductive pattern 122B in the corner isolation portion 220C. The polysilicon plug 224 may contact the second conductive pattern 122B. The polysilicon plug 224 may include doped polysilicon, undoped polysilicon, or a combination thereof. The polysilicon plug 224 may not include air gaps and voids.

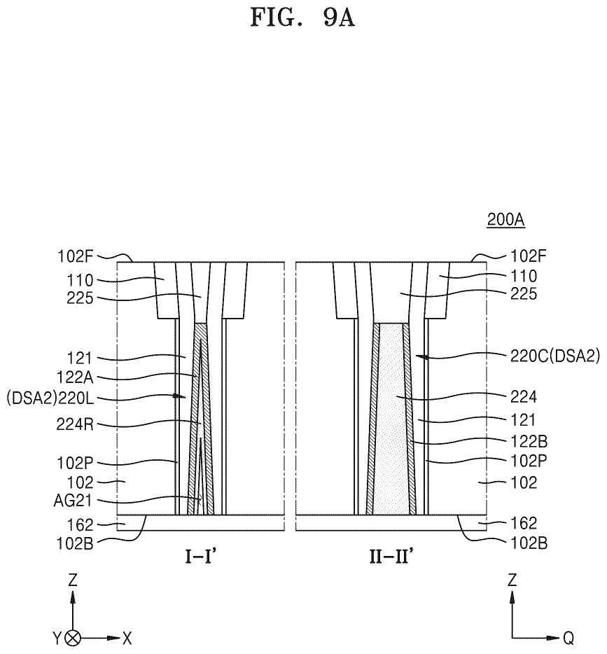

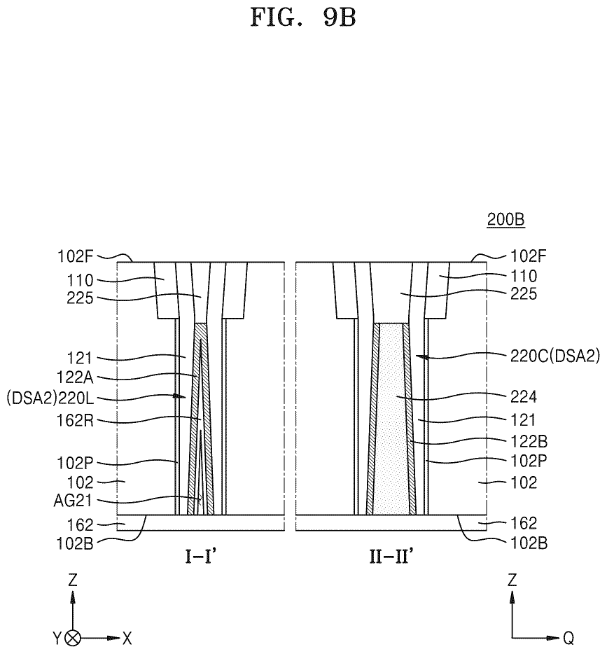

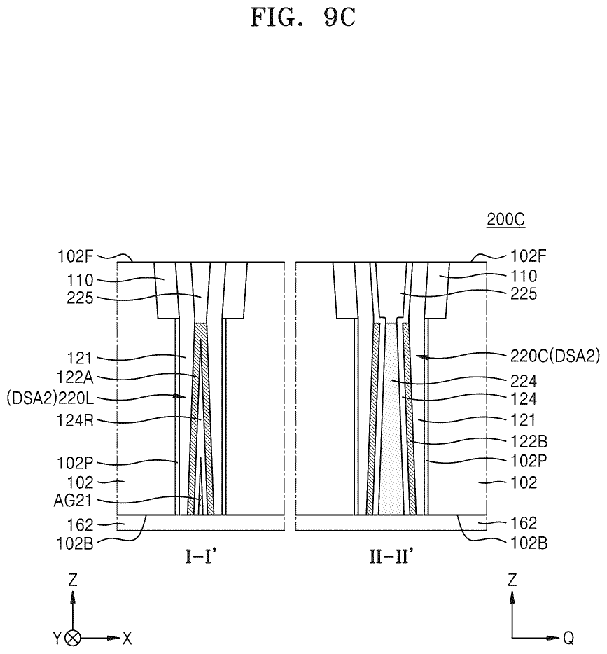

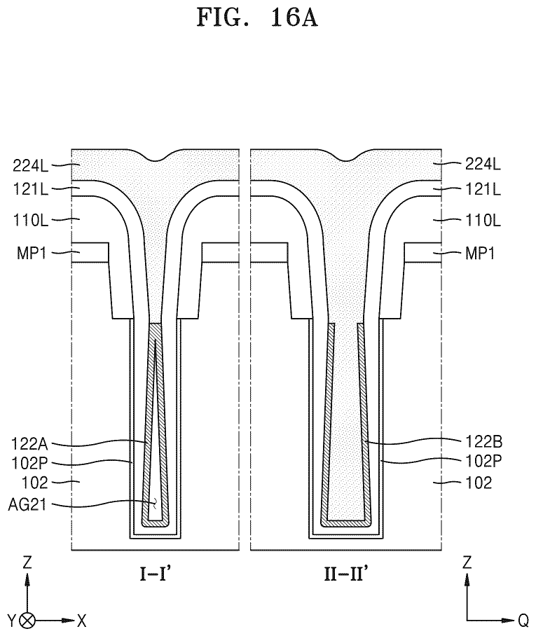

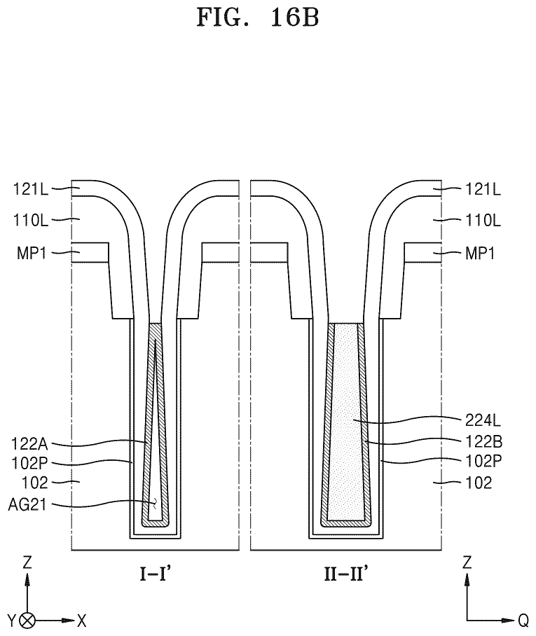

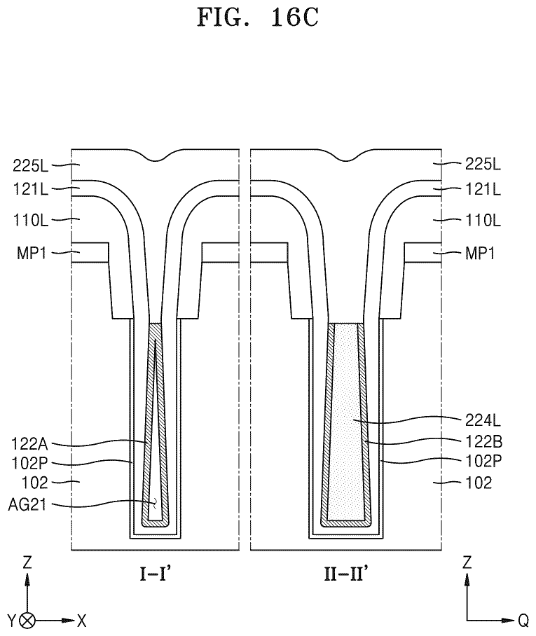

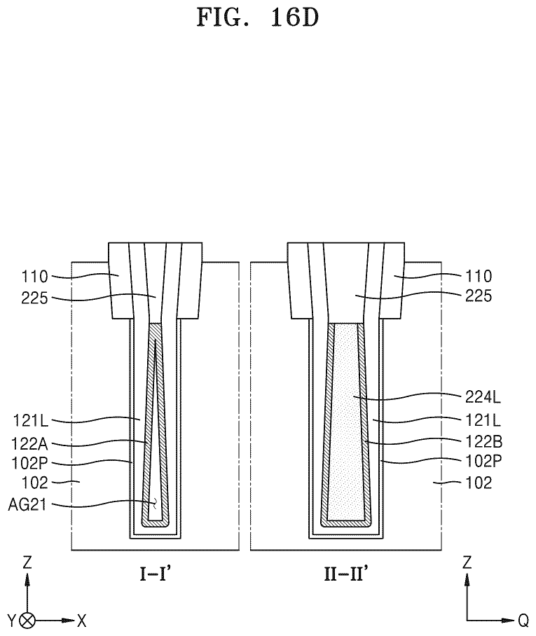

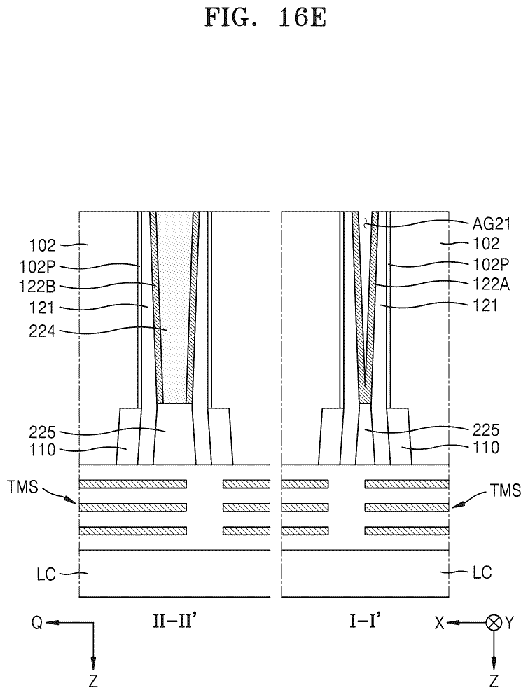

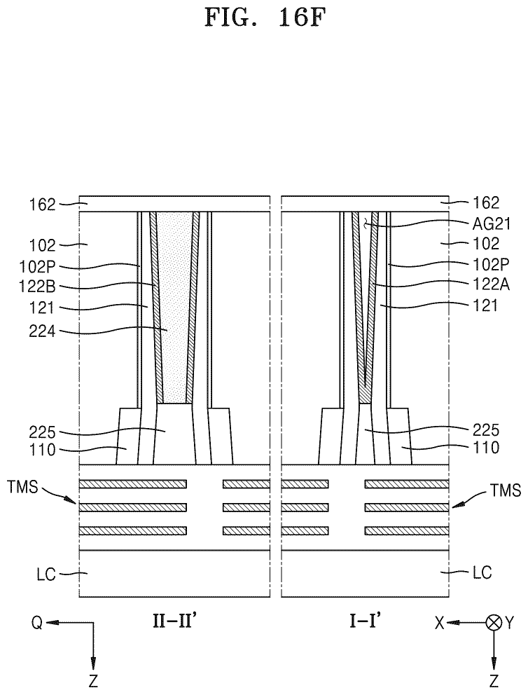

Referring to FIG. 9A, the image sensor 200A may substantially have the same configuration as the image sensor 200 described with reference to FIG. 8. However, in the image sensor 200A, a line isolation portion 220L may further include an inner polysilicon film 224R between a first conductive pattern 122A and a first air gap AG21. In the line isolation portion 220L, the inner polysilicon film 224R may be surrounded by the first conductive pattern 122A. The inner polysilicon film 224R may include the same material as the polysilicon plug 224. In one or more embodiments, during the formation of the polysilicon plug 224 (e.g., during the formation of a polysilicon film 224L in the process described with reference to FIG. 16A), reactants required to form the polysilicon film 224L may move to a deep trench T2A through a deep trench T2B. Accordingly, the inner polysilicon film 224R including the same material as the polysilicon film 224L may be formed also inside the first air gap AG21 in the deep trench T2A.

Referring to FIG. 9B, the image sensor 200B may substantially have the same configuration as the image sensor 200 described with reference to FIG. 8. However, in the image sensor 200B, a line isolation portion 220L may further include an inner insulating film 162R between a first conductive pattern 122A and a first air gap AG21. In the line isolation portion 220L, the inner insulating film 162R may constitute an inner insulating structure surrounded by the first conductive pattern 122A.

Referring to FIG. 9C, the image sensor 200C may substantially have the same configuration as the image sensor 200 described with reference to FIG. 8. However, in the image sensor 200C, a line isolation portion 220L may further include an inner insulating film 124R between a first conductive pattern 122A and a first air gap AG21. In a line isolation portion 220L, the inner insulating film 124R may constitute an inner insulating structure surrounded by the first conductive pattern 122A. In the image sensor 200C, a corner isolation portion 220C may further include a second insulating pattern 124 between the polysilicon plug 224 and a second conductive pattern 122B. In the corner isolation portion 220C, the polysilicon plug 224 and at least a portion of the second conductive pattern 122B may be apart from each other with the second insulating pattern 124 therebetween and may not be in direct contact with each other.

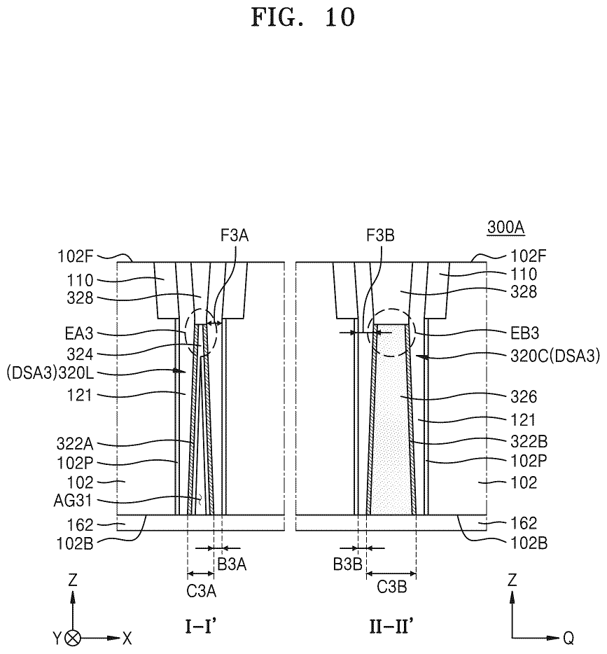

Referring to FIG. 10, the image sensor 300A may substantially have the same configuration as the image sensor 100A described with reference to FIGS. 3 to 5B. However, in the image sensor 300A, a line isolation portion 320L of a pixel isolation structure DSA3 may include a first insulating pattern 121, a first conductive pattern 322A, a first air gap AG31, a second insulating pattern 324, and a third insulating pattern 328. In the line isolation portion 320L, the second insulating pattern 324 may constitute an inner insulating structure surrounded by the first conductive pattern 322A. In the line isolation portion 320L, the third insulating pattern 328 may overlap the second insulating pattern 324 and the first air gap AG31 in a vertical direction (Z direction). The third insulating pattern 328 may include a portion contacting the first conductive pattern 322A and a portion that faces a local device isolation film 110 with the first insulating pattern 121 therebetween in a lateral direction (or X direction in FIG. 10). A constituent material of each of the second insulating pattern 324 and the third insulating pattern 328 may substantially be the same as that of the first insulating pattern 121, which is described above with reference to FIG. 5B.

A corner isolation portion 320C of the pixel isolation structure DSA3 may include a first insulating pattern 121, a second conductive pattern 322B, a polysilicon plug 326, and a third insulating pattern 328. The first insulating pattern 121 of the corner isolation portion 320C may be integrally connected to the first insulating pattern 121 of the line isolation portion 320L. In the corner isolation portion 320C, the first insulating pattern 121 may include an inner surface contacting the second conductive pattern 322B and an outer surface contacting the local device isolation film 110. The third insulating pattern 328 of the corner isolation portion 320C may be integrally connected to the third insulating pattern 328 of the line isolation portion 320L. The third insulating pattern 328 of the corner isolation portion 320C may be at the center of the corner isolation portion 320C. The third insulating pattern 328 of the corner isolation portion 320C may overlap the polysilicon plug 326 in the vertical direction (Z direction) and contact each of the polysilicon plug 326 and the second conductive pattern 322B. In a lateral direction (or X direction in FIG. 10), the third insulating pattern 328 of the corner isolation portion 320C may include a portion that faces the local device isolation film 110 with the first insulating pattern 121 therebetween.

Constituent materials of the first conductive pattern 322A and the second conductive pattern 322B may respectively and substantially be the same as those of the first conductive pattern 122A and the second conductive pattern 122B, which are described above with reference to FIG. 5B. The polysilicon plug 326 may be surrounded by the second conductive pattern 322B and fill a space defined by the second conductive pattern 322B in the corner isolation portion 320C. The polysilicon plug 326 may contact the second conductive pattern 322B. The polysilicon plug 326 may not include air gaps and voids. The polysilicon plug 326 may include doped polysilicon, undoped polysilicon, or a combination thereof. The doped polysilicon may include a P-type dopant or an N-type dopant.

In the lateral direction (e.g., X direction in FIG. 10) of the first insulating pattern 121 of the line isolation portion 320L, a width F3A of a portion that is adjacent to a frontside surface 102F of a substrate 102 and covers the first conductive pattern 322A may be greater than a width B3A of a portion that is adjacent to a backside surface 102B of the substrate 102 and covers the first conductive pattern 322A. In the lateral direction (or X direction in FIG. 10) of the first insulating pattern 121 of the corner isolation portion 320C, a width F3B of a portion that is adjacent to the front surface 102F of the substrate 102 and covers the second conductive pattern 322B may be greater than a width B3B of a portion that is adjacent to the backside surface 102B of the substrate 102 and covers the second conductive pattern 322B.

In the lateral direction (or X direction in FIG. 10) a maximum width C3A of the first conductive pattern 322A included in the line isolation portion 320L may be less than a maximum width C3B of the second conductive pattern 322B included in the corner isolation portion 320C. A width of each of the first conductive pattern 322A and the second conductive pattern 322B in the lateral direction (or X direction in FIG. 5B) may vary along the vertical direction (Z direction). For example, in the pixel isolation structure DSA3, each of the first conductive pattern 322A and the second conductive pattern 322B may have a tapered cross-sectional shape with a width in the lateral direction (or X direction in FIG. 10) gradually increasing from the frontside surface 102F of the substrate 102 toward the backside surface 102B thereof. Accordingly, each of the first conductive pattern 322A and the second conductive pattern 322B may include a tapered surface, which faces a photodiode PD and is inclined with respect to the backside surface 102B of the substrate 102.

Each of the first conductive pattern 322A and the second conductive pattern 322B may have a width in the lateral direction (or X direction in FIG. 10) gradually decreasing toward the local device isolation film 110 in the vertical direction (Z direction). Each of the first conductive pattern 322A and the second conductive pattern 322B may include a pair of inclined patterns inclined in mutually opposite direction with respect to the vertical direction (Z direction). That is, the left pattern of the pair of inclined patterns may be inclined at an opposite direction with respect to the vertical direction as opposed to the right pattern of the pair of inclined patterns. As shown in dashed areas EA3 and EB3 of FIG. 10, the pair of inclined patterns of each of the first conductive pattern 322A and the second conductive pattern 322B may be spaced apart from each other at a position closest to the local device isolation film 110. Constituent materials of the first conductive pattern 322A and the second conductive pattern 322B may respectively and substantially be the same as those of the first conductive pattern 122A and the second conductive pattern 122B, which are described above with reference to FIG. 5B.

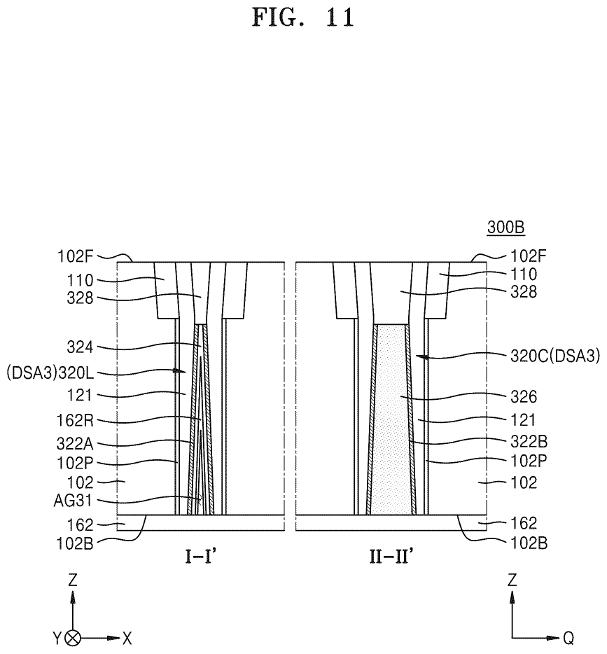

Referring to FIG. 11, the image sensor 300B may substantially have the same configuration as the image sensor 300A described with reference to FIG. 10. However, in the image sensor 300B, a line isolation portion 320L may further include an inner insulating film 162R between a first conductive pattern 322A and a first air gap AG31. In the line isolation portion 320L, the inner insulating film 162R may constitute an inner insulating structure surrounded by the first conductive pattern 322A.

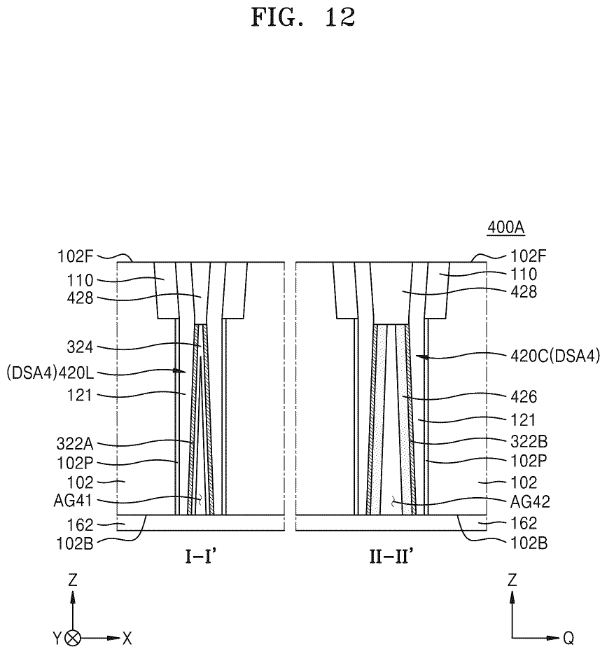

Referring to FIG. 12, the image sensor 400A may substantially have the same configuration as the image sensor 100A described with reference to FIGS. 3 to 5B. However, in the image sensor 400A, a line isolation portion 420L of a pixel isolation structure DSA4 may include a first insulating pattern 121, a first conductive pattern 322A, a first air gap AG41, a second insulating pattern 324, and a third insulating pattern 428. In the line isolation portion 420L, the second insulating pattern 324 may constitute an inner insulating structure surrounded by the first conductive pattern 322A. In the line isolation portion 420L, the third insulating pattern 428 may overlap the second insulating pattern 324 and the first air gap AG41 in a vertical direction (Z direction). The third insulating pattern 428 may include a portion contacting the first conductive pattern 322A and a portion that faces a local device isolation film 110 with the first insulating pattern 121 therebetween in a lateral direction (or X direction in FIG. 12). A constituent material of each of the second insulating pattern 324 and the third insulating pattern 428 may substantially be the same as that of the first insulating pattern 121, which is described above with reference to FIG. 5B.

A corner isolation portion 420C of the pixel isolation structure DSA4 may include a first insulating pattern 121, a second conductive pattern 322B, a polysilicon liner 426, a second air gap AG42, and a third insulating pattern 428. The first insulating pattern 121 of the corner isolation portion 420C may be integrally connected to the first insulating pattern 121 of the line isolation portion 420L. In the corner isolation portion 420C, the first insulating pattern 121 may include an inner surface contacting the second conductive pattern 322B and an outer surface contacting the local device isolation film 110. The third insulating pattern 428 of the corner isolation portion 420C may be integrally connected to the third insulating pattern 428 of the line isolation portion 420L. The third insulating pattern 428 of the corner isolation portion 420C may be at the center of the corner isolation portion 420C. The third insulating pattern 428 of the corner isolation portion 420C may overlap the polysilicon liner 426 in the vertical direction (Z direction) and contact each of the polysilicon liner 426 and the second conductive pattern 322B. In the lateral direction (or X direction in FIG. 12), the third insulating pattern 428 of the corner isolation portion 420C may include a portion that faces the local device isolation film 110 with the first insulating pattern 121 therebetween.

In the corner isolation portion 420C, the second air gap AG42 may be surrounded by the polysilicon liner 426 and the second conductive pattern 322B. In the corner isolation portion 420C, the polysilicon liner 426 may be surrounded by the second conductive pattern 322B and define the second air gap AG42. The polysilicon liner 426 may be between the second conductive pattern 322B and the second air gap AG42 and in contact with the second conductive pattern 322B.

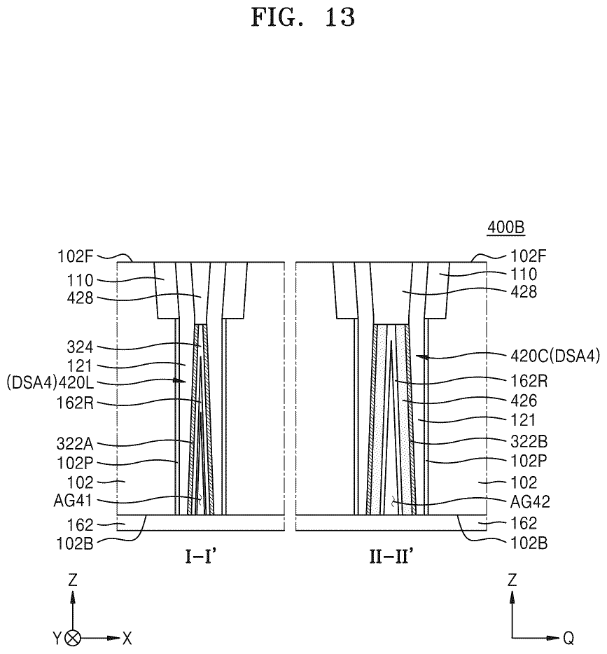

Referring to FIG. 13, the image sensor 400B may substantially have the same configuration as the image sensor 400A described with reference to FIG. 12. However, in the image sensor 400B, a line isolation portion 420L may further include an inner insulating film 162R between a first conductive pattern 322A and a first air gap AG41, and a corner isolation portion 420C may further include an inner insulating film 162R between a polysilicon liner 426 and a second air gap AG42. In the line isolation portion 420L, the inner insulating film 162R may constitute an inner insulating structure surrounded by the first conductive pattern 322A. In the corner isolation portion 420C, the inner insulating film 162R may constitute an inner insulating structure surrounded by the polysilicon liner 426.

Exemplary structures of the image sensors 100B, 100C, 200, 200A, 200B, 200C, 300A, 300B, 400A, and 400B described with reference to FIGS. 7A, 7B, 8, 9A, 9B, 9C, 10, 11, 12, and 13 may each constitute a portion of the image sensor 100 shown in FIGS. 1 and 2. The image sensors 100B, 100C, 200, 200A, 200B, 200C, 300A, 300B, 400A, and 400B described with reference to FIGS. 7A, 7B, 8, 9A, 9B, 9C, 10, 11, 12, and 13 may include the pixel isolation structures DSA, DSA2, DSA3, and DSA4, which extend through the substrate 102 in the vertical direction (Z direction) to define a plurality of unit pixels PX and have network-type planar structures. Accordingly, like the image sensor 100A described with reference to FIGS. 3 to 5B, issues, such as shift, collapse, deformation, etc., of the pixel isolation structures DSA, DSA2, DSA3, and DSA4 and peripheral components thereof may be prevented during and/or after the manufacture of the image sensors 100B, 100C, 200, 200A, 200B, 200C, 300A, 300B, 400A, and 400B. Furthermore, by applying a negative bias to the pixel isolation structures DSA, DSA2, DSA3, and DSA4, characteristics (e.g., a dark current and white spots) of each of all the unit pixels PX defined by the pixel isolation structures DSA, DSA2, DSA3, and DSA4 may be effectively controlled. Accordingly, the sensitivity and resolution of the image sensors 100B, 100C, 200, 200A, 200B, 200C, 300A, 300B, 400A, and 400B may be improved.

Next, a method of manufacturing an image sensor, according to one or more embodiments, is described.

FIGS. 14A to 14N are cross-sectional views illustrating a method of manufacturing an image sensor, according to one or more example embodiments. FIG. 14O is a cross-sectional view illustrating a modified example of the method of manufacturing the image sensor, which is described with reference to FIGS. 14A to 14N, according to one or more example embodiments. FIGS. 14A to 14O illustrate cross-sectional configurations of portions corresponding to the cross-sections taken along lines I-I′ and II-II′ of FIG. 4, according to a process sequence. An example of a method of manufacturing the image sensor 100A shown in FIGS. 3 to 5B is described with reference to FIGS. 14A to 14N and 14O. In FIGS. 14A to 14O, the same reference numerals are used to denote the same elements as in FIGS. 1 to 5B, and detailed descriptions thereof may be omitted here.

Referring to FIG. 14A, a mask pattern MP1 may be formed to cover partial regions of a frontside surface 102F of a substrate 102, and the partial regions of the substrate 102 may be etched using the mask pattern MP1 as an etch mask, and thus, shallow trenches T1A and T1B may be formed in regions of the substrate 102 in which the line isolation portion (refer to 120L in FIG. 4) and a corner isolation portion (refer to 120C in FIG. 4) will be formed. A width TW1 of a portion of the shallow trenches TIA and T1B, which corresponds to the line isolation portion 120L, may be less than a width TW2 of a portion of the shallow trenches T1A and T1B, which corresponds to the corner isolation portion 120C. In one or more embodiments, the mask pattern MP1 may include a buffer oxide film and a silicon nitride film, which are sequentially stacked on the substrate 102.

Referring to FIG. 14B, a local insulating pattern 110L may be formed on the resultant structure of FIG. 14A. The formation of the local insulating pattern 110L may include forming a silicon oxide film to cover the resultant structure of FIG. 14A and patterning the silicon oxide film to expose a portion of the substrate 102 at bottom surfaces of the shallow trenches T1A and T1B.

Referring to FIG. 14C, partial regions of the substrate 102 may be etched using the local insulating pattern 110L as an etch mask to form deep trenches T2A and T2B. A width of a portion of the deep trenches T2A and T2B, which corresponds to the line isolation portion (refer to 120L in FIG. 4), may be less than a width of a portion of the deep trenches T2A and T2B, which corresponds to the corner isolation portion (refer to 120C in FIG. 4). While the substrate 102 is being etched to form the deep trenches T2A and T2B, a portion of the local insulating pattern 110L may be consumed, and thus, an aperture width of the local insulating pattern 110L may increase near entrances of the deep trenches T2A and T2B.

Referring to FIG. 14D, after an ion implantation process may be performed on the substrate 102 through the deep trenches T2A and T2B, the resultant structure may be annealed, and thus, a doped isolation liner 102P may be formed on surfaces of the substrate 102, which are exposed at the deep trenches T2A and T2B.

Referring to FIG. 14E, a first insulating film 121L may be formed to cover the doped isolation liner 102P inside each of the deep trenches T2A and T2B and an exposed surface of the local insulating pattern 110L. A constituent material of the first insulating film 121L may substantially be the same as that of the first insulating pattern 121, which is described above.

The first insulating film 121L may be formed using an atomic layer deposition (ALD) process, a chemical vapor deposition (CVD) process, or a combination thereof. In one or more embodiments, the formation of the first insulating film 121L may include, initially, forming a portion of the first insulating film 121L using an ALD process and forming a remaining portion of the first insulating film 121L using a CVD process. During the formation of the remaining portion of the first insulating film 121L, a deposition process of forming the first insulating film 121L may be performed under conditions where step coverage characteristics are relatively deteriorated. As a result, after the first insulating film 121L is formed, a thickness of the first insulating film 121L may become greater at the entrances of the deep trenches T2A and T2B (i.e., at boundaries between the shallow trenches T1A and T1B and the deep trenches T2A and T2B) than in other portions. Thus, opening widths of the entrances of the deep trenches T2A and T2B may be smaller than widths of other portions of the deep trenches T2A and T2B at the boundaries between the shallow trenches T1A and T1B and the deep trenches T2A and T2B.

In one or more embodiments, at the boundary between the shallow trench T1A and the deep trench T2A in the portions corresponding to the cross-section taken along line I-I′ of FIG. 4, the first insulating film 121L may be formed such that portions of the first insulating film 121L come into contact with each other at the entrance of the deep trench T2A to block the entrance of the deep trench T2A. In one or more embodiments, at the boundary between the shallow trench T1B and the deep trench T2B in the portions corresponding to the cross-section taken along line II-II′ of FIG. 4, the thickness of the first insulating film 121L may become greater than thicknesses of other portions. Thus, the opening width of the entrance of the deep trench T2B may be smaller than the width of the other portion of the deep trench T2B.

In one or more embodiments, the first insulating film 121L may include a silicon oxide film, a silicon nitride film, or a combination thereof. The formation of the first insulating film 121L may include forming a silicon oxide film using a low-pressure CVD (LPCVD) system by a middle temperature oxidation (MTO) process or a high temperature oxidation (HTO) process. In this case, monosilane or disilane may be used as a silicon precursor. The deposition process of forming the first insulating film 121L may be performed at a temperature selected in a range of about 700° C. to about 850° C. In one or more embodiments, the first insulating film 121L may include a silicon oxide film obtained using a high-density plasma (HDP) deposition process or a plasma-enhanced chemical vapor deposition (PECVD) process.

Referring to FIG. 14F, a doped polysilicon liner 122L conformally covering exposed surfaces in the resultant structure of FIG. 14E may be formed. In one or more embodiments, the doped polysilicon liner 122L may be formed using a CVD process or an ALD process. In one or more embodiments, to conformally form the doped polysilicon liner 122L to a uniform thickness on inner surfaces of the deep trenches T2A and T2B, a Si seeding process may be performed to supply Si seeds to exposed surfaces of the resultant structure of FIG. 14E before the doped polysilicon liner 122L is formed. A Si precursor used for the Si seeding process may include, for example, diisopropylamino silane (DIPAS) and hexachorodisilane (HCDS), without being limited thereto.

As shown in a dashed area A11 of FIG. 14F, an entrance of the deep trench T2A, which is a boundary between the shallow trench TIA and the deep trench T2A, may be blocked by the doped polysilicon liner 122L in a portion of the doped polysilicon liner 122L, which corresponds to the line isolation portion (refer to 120L in FIG. 5B). As a result, a first air gap AG11 defined by the doped polysilicon liner 122L may be formed inside the deep trench T2A. After the doped polysilicon liner 122L is formed, an entrance of a portion of the deep trench T2B, which corresponds to the corner isolation portion (refer to 120C in FIG. 5B), may remain connected to the outside as shown in a dashed area A12 of FIG. 14F.

Referring to FIG. 14G, an exposed upper portion of the doped polysilicon liner 122L may be partially removed from the resultant structure of FIG. 14F to expose an upper portion of the first insulating film 121L. As a result, a portion of the doped polysilicon liner 122L may remain as a first conductive pattern 122A defining the first air gap AG11 inside the deep trench T2A, and another portion of the doped polysilicon liner 122L may remain as a second conductive pattern 122B covering the first insulating film 121L inside the deep trench T2B.

Referring to FIG. 14H, a second insulating film 124L may be formed on the resultant structure of FIG. 14G. A constituent material of the second insulating film 124L may be the same as that of the second insulating pattern 124, which is described above. The second insulating film 124L may be formed using an ALD process, a CVD process, or a combination thereof.

In one or more embodiments, because the deep trench T2A is blocked by the first conductive pattern 122A defining the first air gap AG11, the second insulating film 124L may be formed inside the deep trench T2B but may not be formed inside the deep trench T2A.

In one or more embodiments, because a portion of the deep trench T2A, which corresponds to the line isolation portion 120L, is connected to the portion of the deep trench T2B, which corresponds to the corner isolation portion 120C, reactants required to form the second insulating film 124L may move to the deep trench T2A through the deep trench T2B during the formation of the second insulating film 124L. In this case, as shown in FIG. 14O, a portion of the second insulating film 124L may be formed also inside the first air gap AG11 in the deep trench T2A. The portion of the second insulating film 124L, which is formed inside the first air gap AG11, may be removed by a cleaning process after subsequent processes (e.g., a process described below with reference to FIG. 14M). Alternatively, as described above with reference to FIG. 6A, a portion of the second insulating film 124L, which is formed inside the first air gap AG11, may not be removed but remain as an inner insulating film 124R inside the first air gap AG11.

Referring to FIG. 14I, a third insulating film 125L may be formed on the resultant structure of FIG. 14H. A constituent material of the third insulating film 125L may substantially be the same as that of the third insulating pattern 125, which is described above. The third insulating film 125L may be formed using an ALD process, a CVD process, or a combination thereof. In one or more embodiments, after the third insulating film 125L is formed, an annealing process may be performed to densify the third insulating film 125L.

During the formation of the third insulating film 125L, an entrance of the deep trench T2B, which is a boundary between the shallow trench T1B and the deep trench T2B, may be blocked by the third insulating film 125L in a portion corresponding to the corner isolation portion 120C. As a result, a second air gap AG12 may be formed inside the deep trench T2B.

Referring to FIG. 14J, the resultant structure of FIG. 14I may be planarized using a chemical mechanical polishing (CMP) process to expose a top surface of the mask pattern MP1.

Referring to FIG. 14K, the mask pattern MP1 may be removed from the resultant structure of FIG. 14J to expose the substrate 102.

Referring to FIG. 14L, as shown in FIGS. 3 and 5A, various processes required for the manufacture of the image sensor 100A may be performed on the resultant structure of FIG. 14K. For example, a process of forming a plurality of photodiodes PD in a sensor array area SA by implanting impurity ions into the substrate 102 from the frontside surface 102F of the substrate 102, a process of forming a plurality of transistors including a transfer transistor TX by forming a gate dielectric film and a plurality of gate structures on the frontside surface 102F of the substrate 102, and a process of forming a floating diffusion region FD by implanting impurity ions into a partial region of the substrate 102 from the frontside surface 102F of the substrate 102 may be performed. The plurality of gate structures may include gate structures that constitute transistors required to drive a plurality of unit pixels PX included in the image sensor 100A. Thereafter, a wiring structure TMS may be formed to cover the plurality of gate structures. Although the wiring structure TMS is illustrated in a simplified manner in FIG. 14L and drawings described later, a detailed configuration of the wiring structure TMS is the same as that described with reference to FIGS. 3 and 5A.

Referring to FIG. 14M, in the resultant structure of FIG. 14L, a first semiconductor chip LC may be bonded onto the wiring structure TMS using the bonding layer (refer to BL in FIG. 3) included in the wiring structure TMS, and the obtained resultant structure may be rotated such that the substrate 102 faces upward in a vertical direction (Z direction). Thereafter, an exposed portion of the substrate 102 and a portion of each of the doped isolation liner 102P, the first insulating film 121L, the first and second conductive patterns 122A and 122B, the second insulating film 124L, and the third insulating film 125L may be removed using a mechanical grinding process, a CMP process, a wet etching process, or a combination thereof, and thus, the first air gap AG11 and the second air gap AG12 may be exposed to the outside. As a result, remaining portions of the first insulating film 121L, the second insulating film 124L, and the third insulating film 125L may constitute a first insulating pattern 121, a second insulating pattern 124, and a third insulating pattern 123. Although the first semiconductor chip LC is illustrated in a simplified manner in FIG. 14M and drawings described later, a detailed configuration of the first semiconductor chip LC is the same as that described with reference to FIG. 3.

Referring to FIG. 14N, in the resultant structure of FIG. 14M, a backside insulating film 162 may be formed on a backside surface 102B of the substrate 102 and one sectional surface of each of a plurality of pixel isolation structures DSA.

Thereafter, a plurality of grid patterns 164, a first protective film 166, and a plurality of color filters 170 may be formed on the backside insulating film 162 in an active pixel sensor area APS. Afterwards, a microlens 180 and a second protective film 182 may be formed on the plurality of color filters 170 in the active pixel sensor area APS, and thus, the image sensor 100A shown in FIGS. 3 to 5B may be manufactured.

The image sensor 100B shown in FIG. 7A may be manufactured using the processes described with reference to FIGS. 14A to 14N. However, when the backside insulating film 162 is formed in the process described with reference to FIG. 14N, reactants required to form the backside insulating film 162 may be allowed to flow into the first air gap AG11 and the second air gap AG12, and thus, an inner insulating film 162R may be formed to cover surfaces exposed through the first air gap AG11 and the second air gap AG12.

FIGS. 15A to 15C are cross-sectional views illustrating a method of manufacturing an image sensor, according to one or more example embodiments. FIGS. 15A to 15C illustrate cross-sectional configurations of the portions corresponding to the cross-sections taken along lines I-I′ and II-II′ of FIG. 4, according to a process sequence. An example of a method of manufacturing the image sensor 100A shown in FIGS. 3 to 5B or an image sensor having a similar structure thereto is described with reference to FIGS. 15A to 15C. In FIGS. 15A to 15C, the same reference numerals are used to denote the same elements as in FIGS. 1 to 5B, and detailed descriptions thereof may be omitted here.

Referring to FIG. 15A, the processes described with reference to FIGS. 14A to 14E may be performed. However, a first insulating film 121CL may be formed instead of the first insulating film 121L in the process described with reference to FIG. 14E.

The first insulating film 121CL may be formed using a process similar to the process of forming the first insulating film 121L, which is described with reference to FIG. 14E. However, during the formation of the first insulating film 121CL, a deposition process of forming the first insulating film 121CL may be performed under conditions where step coverage characteristics are further deteriorated. Thus, after the first insulating film 121CL is formed, an entrance of a deep trench T2A, which is a boundary between a shallow trench T1A and the deep trench T2A, may be blocked as shown in a dashed area A1C of FIG. 15A. As a result, a first air gap AG11 defined by the first insulating film 121CL may be formed inside the deep trench T2A. During the formation of the first insulating film 121CL, an entrance of a deep trench T2B in a portion of the deep trenches T2A and T2B, which corresponds to a corner isolation portion (refer to 120C in FIG. 5B), may remain connected to the outside as shown in a dashed area A2C of FIG. 15A.

Referring to FIG. 15B, a doped polysilicon liner 122L may be formed on the resultant structure of FIG. 15A using a method similar to the process of forming the doped polysilicon liner 122L, which is described with reference to FIG. 14F.

Referring to FIG. 15C, using a method similar to the process of removing a portion of the doped polysilicon liner 122L, which is described with reference to FIG. 14G, an exposed upper portion of the doped polysilicon liner 122L may be removed from the resultant structure of FIG. 15B to expose an upper portion of the first insulating film 121CL. Afterwards, the processes described with reference to FIGS. 14H to 14N may be performed on the resultant structure of FIG. 15C.

FIGS. 16A to 16F are cross-sectional views illustrating a method of manufacturing an image sensor, according to one or more example embodiments. FIGS. 16A to 16F illustrate cross-sectional configurations of the portions corresponding to the cross-sections taken along lines I-I′ and II-II′ of FIG. 4, according to a process sequence. An example of a method of manufacturing the image sensor 200 shown in FIG. 8 is described with reference to FIGS. 16A to 16F. In FIGS. 16A to 16F, the same reference numerals are used to denote the same elements as in FIGS. 1 to 8, and detailed descriptions thereof may be omitted here.

Referring to FIG. 16A, processes similar to those described with reference to FIGS. 14A and 14G may be performed. Thereafter, a polysilicon film 224L may be formed on the resultant structure of FIG. 14G.

In one or more embodiments, the polysilicon film 224L may include doped polysilicon, undoped polysilicon, or a combination thereof. A portion of the polysilicon film 224L, which corresponds to the line isolation portion (refer to 220L in FIG. 8), may be formed to contact a first conductive pattern 122A and fill a space on the first conductive pattern 122A. A portion of the polysilicon film 224L, which corresponds to the corner isolation portion (refer to 220C in FIG. 8), may be formed to contact a second conductive pattern 122B and fill the inside of a deep trench T2B without air gaps or voids. Even when the polysilicon film 224L is formed to include undoped polysilicon, processes described below may be performed, and thus, a dopant may diffuse from the first and second conductive patterns 122A and 122B into at least a partial region of the polysilicon film 224L. Accordingly, the polysilicon film 224L may be doped with the dopant through a process described below.

Referring to FIG. 16B, in the resultant structure of FIG. 16A, the polysilicon film 224L may be partially removed to expose the first and second conductive patterns 122A and 122B, and thus, an upper portion of the first insulating film 121L may be exposed. As a result, a portion of the polysilicon film 224L, which remains on a substrate 102 and corresponds to the corner isolation portion (refer to 220C in FIG. 8) may fill a region defined by the second conductive pattern 122B.

Referring to FIG. 16C, a second insulating film 225L may be formed on the resultant structure of FIG. 16B. A constituent material of the second insulating film 225L may substantially be the same as that of the second insulating pattern 225, which is described above. The second insulating film 225L may be formed using a CVD process. In one or more embodiments, after the second insulating film 225L is formed, an annealing process may be performed to densify the second insulating film 225L.

Referring to FIG. 16D, processes similar to those described with reference to FIGS. 14J and 14K may be performed on the resultant structure of FIG. 16C, and thus, the substrate 102 may be exposed around a local device isolation film 110.

Referring to FIG. 16E, processes similar to those described with reference to FIGS. 14L and 14M may be performed on the resultant structure of FIG. 14D. Thus, a first air gap AG21 and a polysilicon plug 224 obtained from the polysilicon film 224L may be exposed to the outside.

Referring to FIG. 16F, a backside insulating film 162 may be formed on the resultant structure of FIG. 16E using a method similar that described with reference to FIG. 14N, and subsequent processes described with reference to FIG. 14N may be performed, and thus, the image sensor 200 shown in FIG. 8 may be manufactured.

The image sensor 200B shown in FIG. 9B may be manufactured using the processes described with reference to FIGS. 16A to 16F. However, when the backside insulating film 162 is formed in the process described with reference to FIG. 16F, reactants required to form the backside insulating film 162 may be allowed to flow into the first air gap AG21, and thus, an inner insulating film 162R may be formed to cover surfaces exposed through the first air gap AG21.

The image sensor 200C shown in FIG. 9C may be manufactured using the processes described with reference to FIGS. 16A to 16F. However, before the polysilicon film 224L is formed on the resultant structure of FIG. 14G as described with reference to FIG. 16A, the method may further include forming a second insulating pattern 124 covering the second conductive pattern 122B in a region of the resultant structure of FIG. 14G, which corresponds to the corner isolation portion 220C. Afterwards, a polysilicon plug 224 may be formed to fill a portion of a space defined by the second insulating pattern 124. While the second insulating pattern 124 is being formed in the region of the resultant structure of FIG. 14G, which corresponds to the corner isolation portion 220C, reactants for forming the second insulating pattern 124 may flow into the first air gap AG21 in the line isolation portion 220L. As a result, an inner insulating film 124R covering surfaces exposed through the first air gap AG21 may be formed in the line isolation portion 220L.

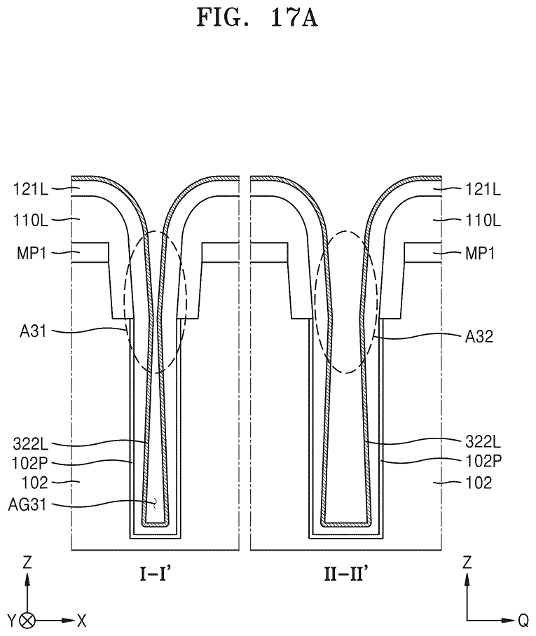

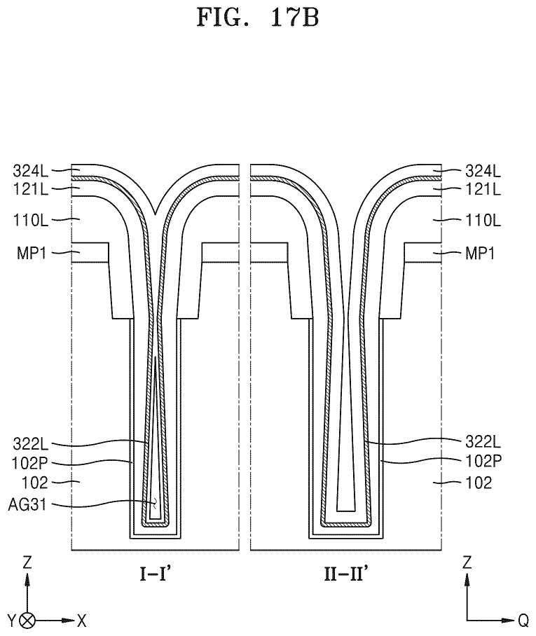

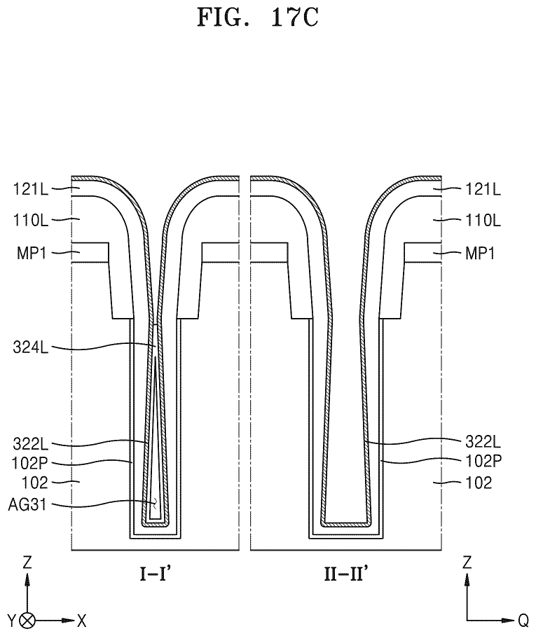

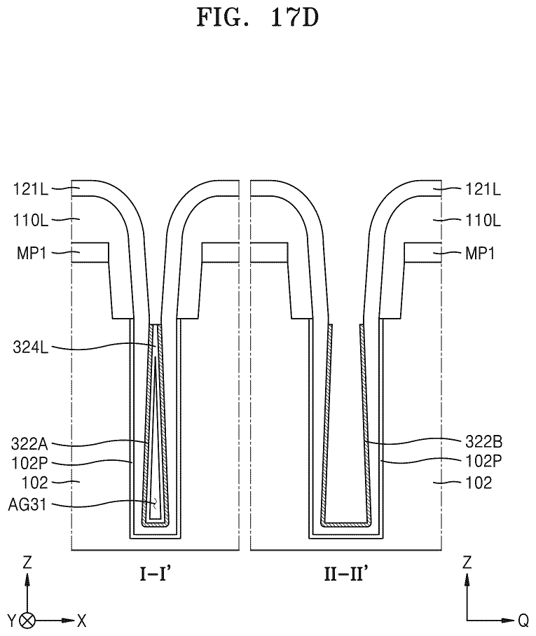

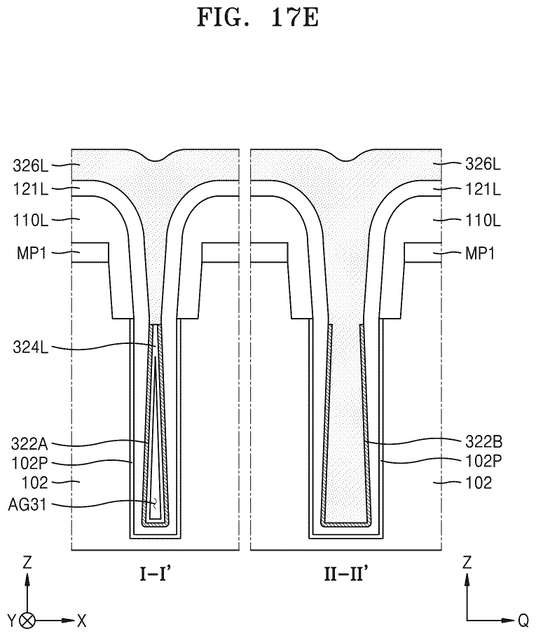

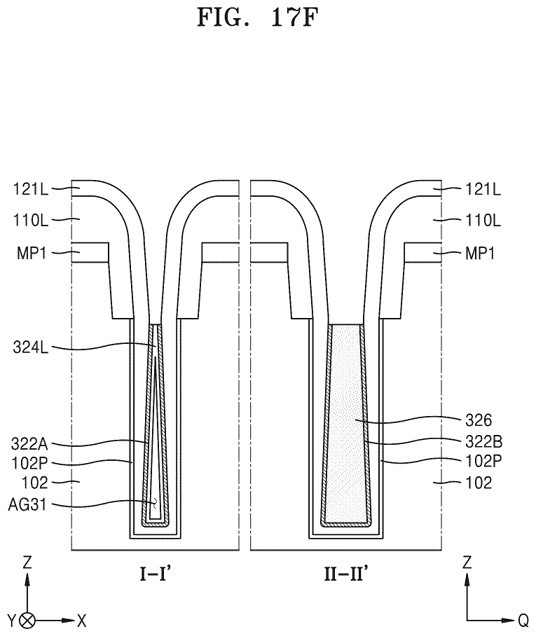

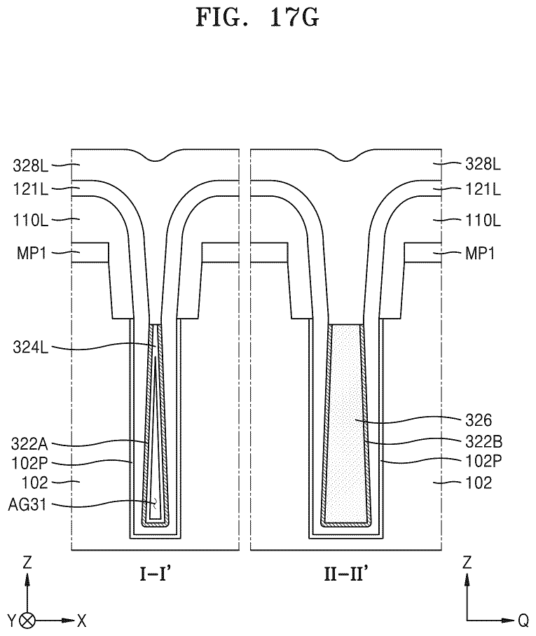

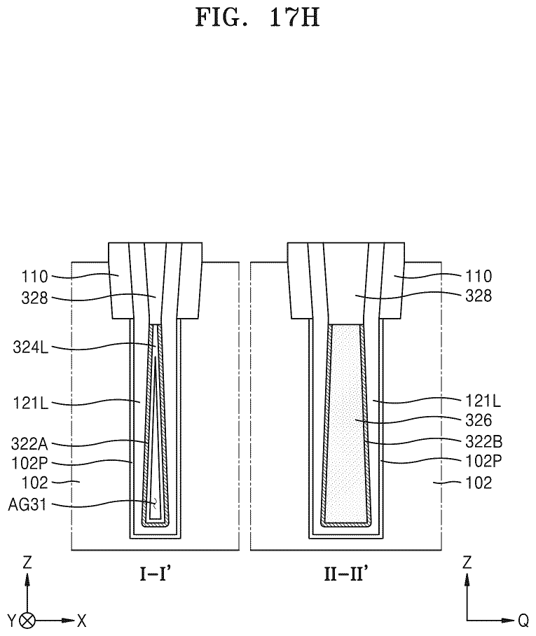

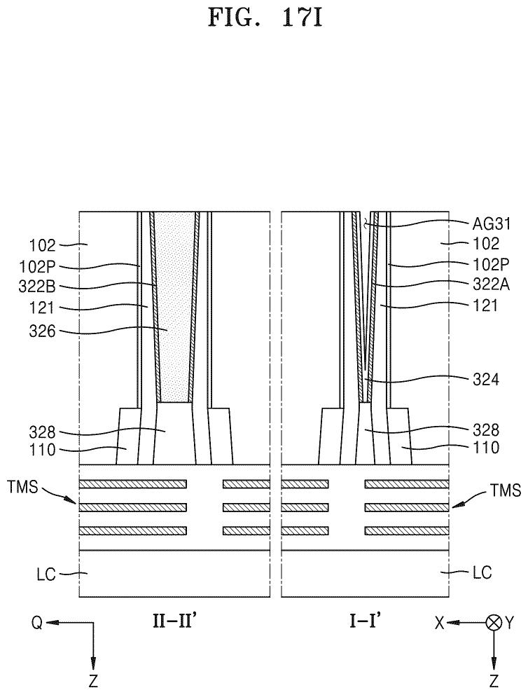

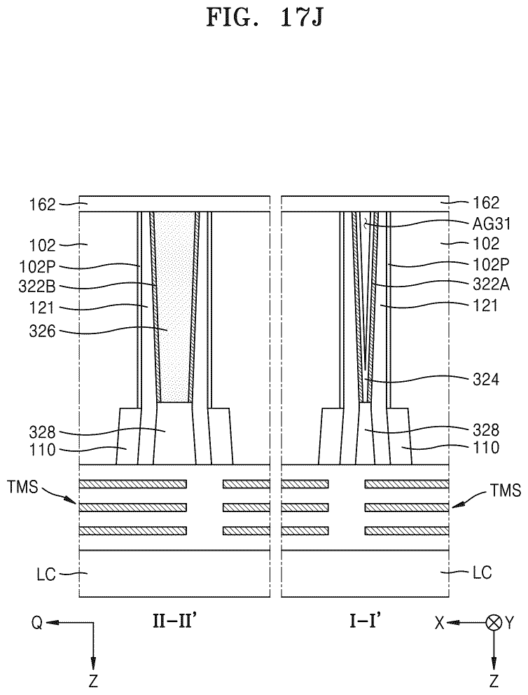

FIGS. 17A to 17J are cross-sectional views illustrating a method of manufacturing an image sensor, according to one or more example embodiments. FIGS. 17A to 17J illustrate cross-sectional configurations of the portions corresponding to the cross-sections taken along lines I-I′ and II-II′ of FIG. 4, according to a process sequence. An example of a method of manufacturing the image sensor 300A shown in FIG. 10 is described with reference to FIGS. 17A to 17J. In FIGS. 17A to 17J, the same reference numerals are used to denote the same elements as in FIGS. 1 to 10, and detailed descriptions thereof may be omitted here.

Referring to FIG. 17A, processes similar to those described with reference to FIGS. 14A and 14E may be performed. Thereafter, a doped polysilicon liner 322L conformally covering exposed surfaces in the resultant structure of FIG. 14E may be formed. In one or more embodiments, the doped polysilicon liner 322L may be formed using a CVD process or an ALD process. The doped polysilicon liner 322L may be formed using a process similar to the process of forming the doped polysilicon liner 122L, which is described with reference to FIG. 14F. However, as shown in a dashed area A31 of FIG. 17A, in a portion of the doped polysilicon liner 322L, which corresponds to a line isolation portion (refer to 320L in FIG. 10), an entrance of a deep trench T2A, which is a boundary between a shallow trench T1A and the deep trench T2A, may remain connected to the outside. In addition, an entrance of a deep trench T2B in a portion of the doped polysilicon liner 322L, which corresponds to a corner isolation portion (refer to 320C in FIG. 10), may remain connected to the outside in a dashed area A32 of FIG. 17A.

Referring to FIG. 17B, a second insulating film 324L may be formed on the resultant structure of FIG. 17A. A constituent material of the second insulating film 324L may substantially be the same as that of a second insulating pattern 324, which is described above. The second insulating film 324L may be formed using an ALD process, a CVD process, or a combination thereof.

During the formation of the second insulating film 324L, it may be relatively difficult for source materials required to form the second insulating film 324L to reach the inside of the deep trench T2A because, of the deep trenches T2A and T2B, the inside of a portion of the deep trench T2A, which corresponds to the line isolation portion 320L, is narrower and deeper than the inside of a portion of the deep trench T2B, which corresponds to the corner isolation portion 220C. Accordingly, a portion of the second insulating film 324L, which is formed inside the deep trench T2A, may have a smaller thickness than other portions of the second insulating film 324L, and the entrance of the deep trench T2A, which is the boundary between the shallow trench T1A and the deep trench T2A, may be blocked by the second insulating film 324L. As a result, a first air gap AG31 defined by the second insulating film 324L may be formed inside the deep trench T2A. During the formation of the second insulating film 324L, an entrance of the deep trench T2B in a portion of the deep trenches T2A and T2B, which corresponds to the corner isolation portion 320C, may remain connected to the outside.

Referring to FIG. 17C, a portion of the second insulating film 324L may be removed from the resultant structure of FIG. 17B such that only a portion of the second insulating film 324L, which defines the first air gap AG31, is left inside the deep trench T2A in a portion of the second insulating film 324L, which corresponds to the line isolation portion 320L. As a result, the doped polysilicon liner 322L may be exposed on the portion of the second insulating film 324L, which corresponds to the line isolation portion 320L, while the doped polysilicon liner 322L may be exposed inside a portion of the deep trench T2B, which corresponds to the corner isolation portion 320C.

Referring to FIG. 17D, an exposed upper portion of the doped polysilicon liner 322L may be removed from the resultant structure of FIG. 17C, and thus, a first conductive pattern 322A and a second conductive pattern 322B may be formed from the doped polysilicon liner 322L.

Referring to FIG. 17E, a polysilicon film 326L may be formed on the resultant structure of FIG. 17D using a method similar to the process of forming the polysilicon film 224L, which is described with reference to FIG. 16A.

The polysilicon film 326L may include doped polysilicon, undoped polysilicon, or a combination thereof. A portion of the polysilicon film 326L, which corresponds to the line isolation portion 320L, may be formed to contact the first conductive pattern 322A and fill a space on the first conductive pattern 322A. A portion of the polysilicon film 326L, which corresponds to the corner isolation portion 320C, may be formed to contact the second conductive pattern 322B and fill the inside of the deep trench T2B without air gaps or voids.

Referring to FIG. 17F, in the resultant structure of FIG. 17E, the polysilicon film 326L may be partially removed to expose the first and second conductive patterns 322A and 322B, and thus, an upper portion of the first insulating film 121L may be exposed. As a result, a portion of the polysilicon film 326L, which remains on a substrate 102 and corresponds to the corner isolation portion 320C, may fill a region defined by the second conductive pattern 322B.

Referring to FIG. 17G, a third insulating film 328L may be formed on the resultant structure of FIG. 17F. A constituent material of the third insulating film 328L may substantially be the same as that of a third insulating pattern 328, which is described above. The third insulating film 328L may be formed using a CVD process. In one or more embodiments, after the third insulating film 328L is formed, an annealing process may be performed to densify the third insulating film 328L.

Referring to FIG. 17H, processes similar to those described with reference to FIGS. 14J and 14K may be performed on the resultant structure of FIG. 17G, and thus, the substrate 102 may be exposed around a local device isolation film 110.

Referring to FIG. 17I, processes similar to those described with reference to FIGS. 14L and 14M may be performed on the resultant structure of FIG. 17H. Thus, the first air gap AG31, the second insulating pattern 324 obtained from the second insulating film 324L, and a polysilicon plug 326 may be exposed to the outside.

Referring to FIG. 17J, a backside insulating film 162 may be formed on the resultant structure of FIG. 17I using a method similar that described with reference to FIG. 14N, and subsequent processes described with reference to FIG. 14N may be performed, and thus, the image sensor 300A shown in FIG. 10 may be manufactured.

The image sensor 400B shown in FIG. 11 may be manufactured using the processes described with reference to FIGS. 17A to 17J. However, when the backside insulating film 162 is formed in the process described with reference to FIG. 17J, reactants required to form the backside insulating film 162 may be allowed to flow into the first air gap AG31, and thus, an inner insulating film 162R may be formed to cover surfaces exposed through the first air gap AG31.

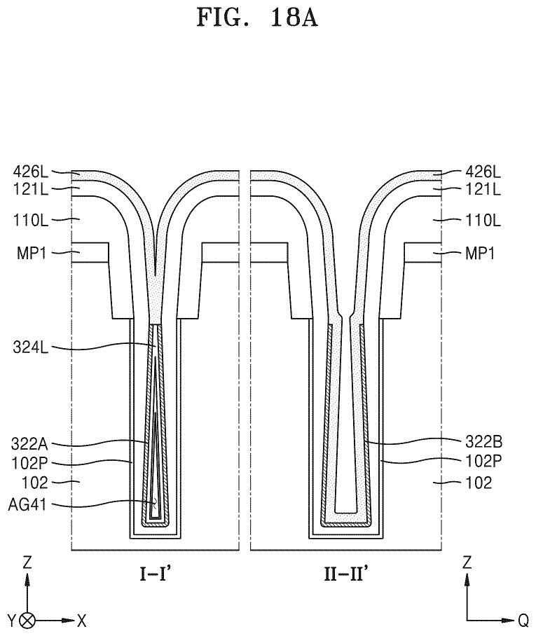

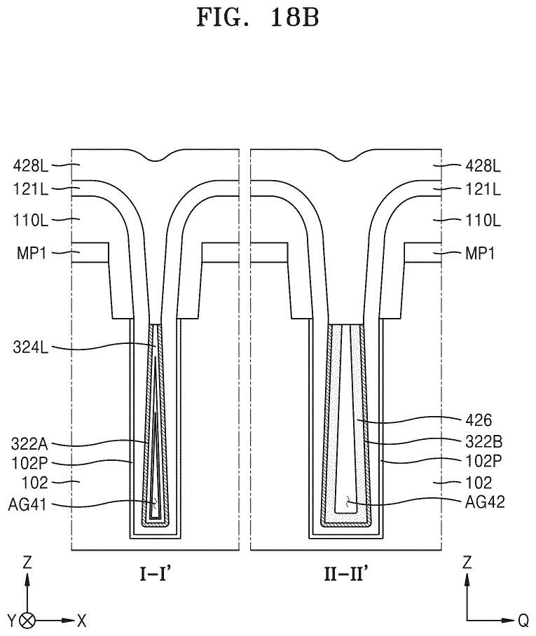

FIGS. 18A and 18B are cross-sectional views illustrating a method of manufacturing an image sensor, according to one or more example embodiments. FIGS. 18A and 18B illustrate cross-sectional configurations of the portions corresponding to the cross-sections taken along lines I-I′ and II-II′ of FIG. 4, according to a process sequence. An example of a method of manufacturing the image sensor 300B shown in FIG. 12 is described with reference to FIGS. 18A and 18B. In FIGS. 18A and 18B, the same reference numerals are used to denote the same elements as in FIGS. 1 to 12, and detailed descriptions thereof may be omitted here.

Referring to FIG. 18A, after the processes described with reference to FIGS. 17A to 17D are performed, a polysilicon film 426L conformally covering exposed surfaces in the resultant structure of FIG. 17D may be formed.

The polysilicon film 426L may include doped polysilicon, undoped polysilicon, or a combination thereof. A portion of the polysilicon film 426L, which corresponds to the line isolation portion (refer to 420L in FIG. 12), may be formed to contact a first conductive pattern 322A and fill a space on the first conductive pattern 322A. Also, the polysilicon film 426L may be formed inside a portion of a deep trench T2B, which corresponds to the corner isolation portion (refer to 420C in FIG. 12), to conformally cover the second conductive pattern 322B to a substantially constant thickness. After the polysilicon film 426L is formed, an inner space of the portion of the deep trench T2B, which corresponds to the corner isolation portion 420C, may remain connected to the outside.

Referring to FIG. 18B, in the resultant structure of FIG. 18A, the polysilicon film 426L may be partially removed to expose the first and second conductive patterns 322A and 322B, and thus, an upper portion of the first insulating film 121L may be exposed. As a result, only a portion of the polysilicon film 426L may be left as a polysilicon liner 426 in a region defined by the second conductive pattern 322B in the portion of the deep trench T2B, which corresponds to the corner isolation portion 420C.

Thereafter, a third insulating film 428L may be formed on the resultant structure including the polysilicon liner 426. A constituent material of the third insulating film 428L may substantially be the same as that of a third insulating pattern 428, which is described above. The third insulating film 428L may be formed using a CVD process. In one or more embodiments, after the third insulating film 428L is formed, an annealing process may be performed to densify the third insulating film 428L.

Afterwards, processes similar to those described with reference to FIGS. 17H to 17J may be performed on the resultant structure of FIG. 18B, and thus, the image sensor 400A described with reference to FIG. 12 may be manufactured.

The image sensor 400B shown in FIG. 13 may be manufactured using the processes described with reference to FIGS. 18A and 18B. However, when a backside insulating film 162 is formed, reactants required to form the backside insulating film 162 may be allowed to flow into a first air gap AG41 and a second air gap AG42, and thus, an inner insulating film 162R may be formed to cover surfaces exposed through the first air gap AG41 and the second air gap AG42.

Although the methods of manufacturing exemplary image sensors have been described with reference to FIGS. 14A to 18B, it will be understood that the image sensors having variously changed structures may be manufactured by applying various modifications and changes to the processes described with reference to FIGS. 14A to 18B within the scope of the disclosure.

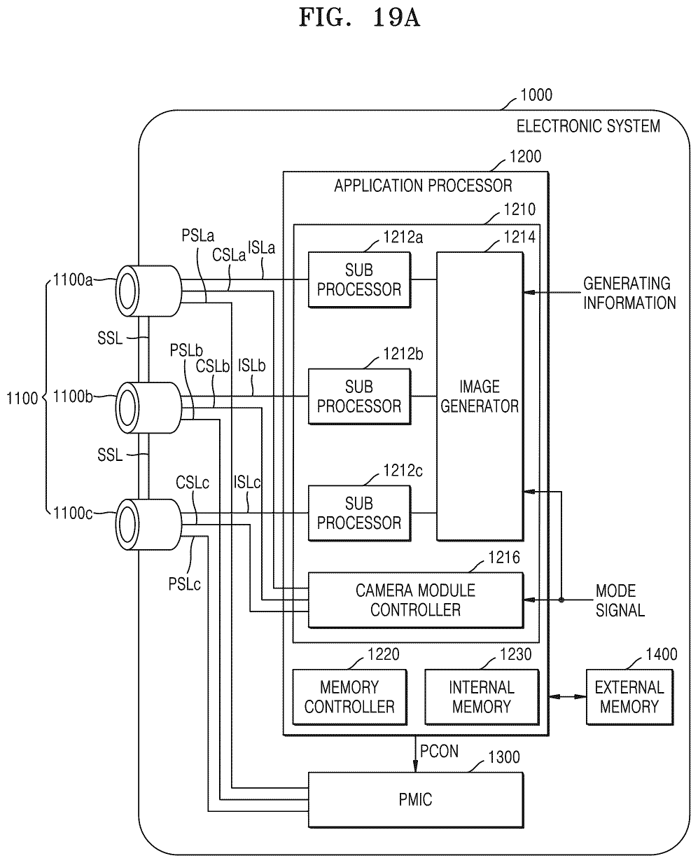

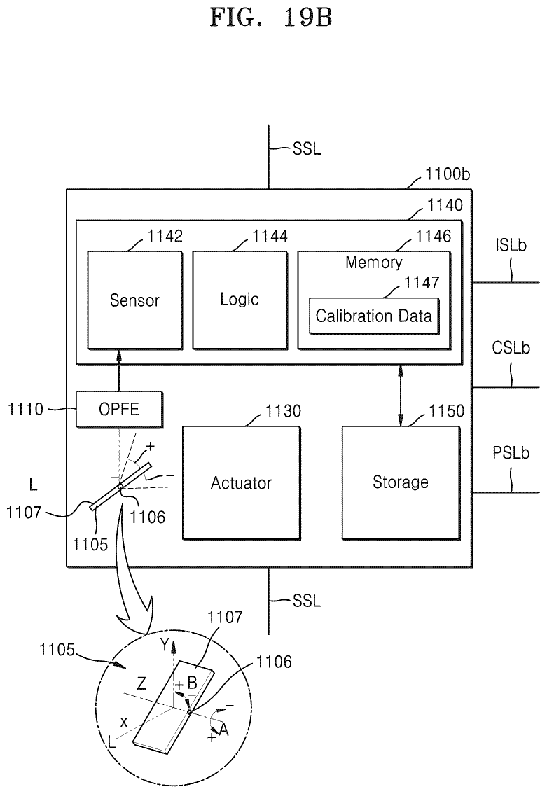

FIG. 19A is a block diagram illustrating an electronic system 1000 according to one or more example embodiments, and FIG. 19B is a block diagram illustrating a camera module included in the electronic system 1000 of FIG. 19A according to one or more example embodiments.

Referring to FIG. 19A, the electronic system 1000 may include a camera module group 1100, an application processor 1200, a power management integrated circuit (PMIC) 1300, and an external memory 1400.

The camera module group 1100 may include a plurality of camera modules (e.g., 1100a, 1100b, and 1100c). Although three camera modules 1100a, 1100b, and 1100c are illustrated in the present embodiment, but the disclosure is not limited thereto. In one or more embodiments, the camera module group 1100 may be modified to include only two camera modules. In one or more embodiments, the camera module group 1100 may be modified to include n camera modules, where n is a natural number of 4 or more.

The detailed configuration of the camera module 1100b will be described with reference to FIG. 19B below. The descriptions below may be also applied to the other camera modules 1100a and 1100c.

Referring to FIG. 19B, the camera module 1100b may include a prism 1105, an optical path folding element (OPFE) 1110, an actuator 1130, an image sensing device 1140, and a storage 1150.

The prism 1105 may include a reflective surface 1107 of a light reflecting material and may change the path of light L incident from the outside.

In one or more embodiments, the prism 1105 may change the path of the light L incident in a first direction (X direction in FIG. 19B) into a second direction (Y direction in FIG. 19B) that is perpendicular to the first direction. The prism 1105 may rotate the reflective surface 1107 of the light reflecting material in a direction A around a central shaft 1106 or rotate the central shaft 1106 in a direction B to change the path of the light L incident in the first direction (X direction) into the second direction (Y direction) perpendicular to the first direction (X direction). In this case, the OPFE 1110 may move in a third direction (Z direction in FIG. 19B), which is perpendicular to the first direction (X direction) and the second direction (Y direction).

In one or more embodiments, as shown in FIG. 19B, an A-direction maximum rotation angle of the prism 1105 may be less than or equal to about 15 degrees in a plus (+) A direction and greater than about 15 degrees in a minus (−) A direction, but the disclosure is not limited thereto.

In one or more embodiments, the prism 1105 may move by an angle of about 20 degrees or in a range from about 10 degrees to about 20 degrees or from about 15 degrees to about 20 degrees in a plus or minus B direction. In this case, an angle by which the prism 1105 moves in the plus B direction may be the same as or similar, within a difference of about 1 degree, to an angle by which the prism 1105 moves in the minus B direction.

In one or more embodiments, the prism 1105 may move the reflective surface 1107 of the light reflecting material in the third direction (e.g., Z direction) parallel with an extension direction of the central shaft 1106.

The OPFE 1110 may include, for example, “m” optical lenses, where “m” is a natural number. The m lenses may move in the second direction (or Y direction) and change an optical zoom ratio of the camera module 1100b. For example, when the default optical zoom ratio of the camera module 1100b is Z, the optical zoom ratio of the camera module 1100b may be changed to 3Z or 5Z or greater by moving the m optical lenses included in the OPFE 1110.

The actuator 1130 may move the OPFE 1110 or an optical lens to a certain position. For example, the actuator 1130 may adjust the position of the optical lens such that an image sensor 1142 is positioned at a focal length of the optical lens for accurate sensing.

The image sensing device 1140 may include the image sensor 1142, a control logic 1144, and a memory 1146. The image sensor 1142 may sense an image of an object using the light L provided through the optical lens. The control logic 1144 may control all operations of the camera module 1100b. For example, the control logic 1144 may control operation of the camera module 1100b according to a control signal provided through a control signal line CSLb.

The memory 1146 may store information, such as calibration data 1147, necessary for the operation of the camera module 1100b. The calibration data 1147 may include information, which is necessary for the camera module 1100b to generate image data using the light L provided from outside. The calibration data 1147 may include information about a degree of rotation, information about a focal length, information about an optical axis, or the like. When the camera module 1100b is implemented as a multi-state camera that has a focal length varying with the position of the optical lens, the calibration data 1147 may include a value of a focal length for each position (or state) of the optical lens and information about auto focusing.

The storage 1150 may store image data sensed by the image sensor 1142. The storage 1150 may be provided outside the image sensing device 1140 and may form a stack with a sensor chip of the image sensing device 1140. In one or more embodiments, the storage 1150 may be implemented as electrically erasable programmable read-only memory (EEPROM), but the disclosure is not limited thereto.

The image sensor 1142 may include the image sensors 100, 100A, 100A1, 100A2, 100A3, 100B, 100C, 200, 200A, 200B, 200C, 300A, 300B, 400A, and 400B described with reference to FIGS. 1 to 13 or image sensors variously modified and changed therefrom within the scope of the disclosure.

Referring to FIGS. 19A and 19B, in one or more embodiments, each of the camera modules 1100a, 1100b, and 1100c may include the actuator 1130. Accordingly, the camera modules 1100a, 1100b, and 1100c may include the calibration data 1147, which is the same or different among the camera modules 1100a, 1100b, and 1100c according to the operation of the actuator 1130 included in each of the camera modules 1100a, 1100b, and 1100c.

In one or more embodiments, one (e.g., the camera module 1100b) of the camera modules 1100a, 1100b, and 1100c may be of a folded-lens type including the prism 1105 and the OPFE 1110, which are described above, while the other camera modules (e.g., the camera modules 1100a and 1100c) may be of a vertical type that does not include the prism 1105 and the OPFE 1110. However, embodiments are not limited thereto.

In one or more embodiments, one (e.g., the camera module 1100c) of the camera modules 1100a, 1100b, and 1100c may include a vertical depth camera, which extracts depth information using an infrared ray (IR). In this case, the application processor 1200 may generate a three-dimensional (3D) depth image by merging image data provided from the depth camera with image data provided from another camera module (e.g., the camera module 1100a or 1100b).

In one or more embodiments, at least two camera modules (e.g., 1100a and 1100b) among the camera modules 1100a, 1100b, and 1100c may have different field-of-views. In this case, for example, the two camera modules (e.g., 1100a and 1100b) among the camera modules 1100a, 1100b, and 1100c may respectively have different optical lenses. However, embodiments are not limited thereto.

In one or more embodiments, the camera modules 1100a, 1100b, and 1100c may have different field-of-views from each other. In this case, although the camera modules 1100a, 1100b, and 1100c may respectively have different optical lenses, the disclosure is not limited thereto.

In one or more embodiments, the camera modules 1100a, 1100b, and 1100c may be physically separated from one another. In other words, a sensing region of the image sensor 1142 is not divided and used by the camera modules 1100a, 1100b, and 1100c, but the image sensor 1142 may be independently included in each of the camera modules 1100a, 1100b, and 1100c.

Referring back to FIG. 19A, the application processor 1200 may include an image processing device 1210, a memory controller 1220, and an internal memory 1230. The application processor 1200 may be separately implemented from the camera modules 1100a, 1100b, and 1100c. For example, the application processor 1200 and the camera modules 1100a, 1100b, and 1100c may be implemented in different semiconductor chips and separated from each other.

The image processing device 1210 may include a plurality of sub-processors (e.g., 1212a, 1212b, and 1212c), an image generator 1214, and a camera module controller 1216. The image processing device 1210 may include sub-processors (e.g., 1212a, 1212b, and 1212c) in number corresponding to the number of camera modules (e.g., 1100a, 1100b, 1100c).

Pieces of image data respectively generated by the camera modules 1100a, 1100b, and 1100c may be respectively provided to the corresponding ones of the sub-processors 1212a, 1212b, and 1212c through image signal lines ISLa, ISLb, and ISLc separated from each other. For example, image data generated by the camera module 1100a may be provided to the sub-processor 1212a through the image signal line ISLa, image data generated by the camera module 1100b may be provided to the sub-processor 1212b through the image signal line ISLb, and image data generated by the camera module 1100c may be provided to the sub-processor 1212c through the image signal line ISLc. Such image data transmission may be performed using, for example, a mobile industry processor interface (MIPI)-based camera serial interface (CSI). However, the disclosure is not limited thereto.

In one or more embodiments, a single sub-processor may be arranged to correspond to a plurality of camera modules. For example, differently from FIG. 19A, the sub-processors 1212a and 1212c may not be separated but may be integrated into a single sub-processor, and the image data provided from the camera module 1100a or the camera module 1100c may be selected by a selection element (e.g., a multiplexer) and then provided to the integrated sub-processor.

The image data provided to each of the sub-processors 1212a, 1212b, and 1212c may be provided to the image generator 1214. The image generator 1214 may generate an output image using the image data provided from each of the sub-processors 1212a, 1212b, and 1212c according to image generation information or a mode signal.

Specifically, the image generator 1214 may generate the output image by merging at least portions of respective pieces of image data, which are respectively generated by the camera modules 1100a, 1100b, and 1100c having different field-of-views, according to the image generation information or the mode signal. Alternatively, the image generator 1214 may generate the output image by selecting one of pieces of image data, which are respectively generated by the camera modules 1100a, 1100b, and 1100c having different field-of-views, according to the image generation information or the mode signal.

In one or more embodiments, the image generating information may include a zoom signal or a zoom factor. In one or more embodiments, the mode signal may be based on a mode selected by a user.

When the image generation information includes a zoom signal or a zoom factor and the camera modules 1100a, 1100b, and 1100c have different field-of-views, the image generator 1214 may perform different operations according to different kinds of zoom signals. For example, when the zoom signal is a first signal, the image generator 1214 may merge image data output from the camera module 1100a and image data output from the camera module 1100c and then generate an output image using a merged image signal and image data output from the camera module 1100b and not used for merging. When the zoom signal is a second signal different from the first signal, the image generator 1214 may generate an output image by selecting one of the pieces of image data respectively output from the camera modules 1100a, 1100b, and 1100c, instead of performing the merging. However, the disclosure is not limited thereto, and a method of processing image data may be changed whenever necessary.

In one or more embodiments, the image generator 1214 may receive a plurality of pieces of image data, which have different exposure times, from at least one of the sub-processors 1212a, 1212b, and 1212c and perform high dynamic range (HDR) processing on the pieces of image data, thereby generating merged image data having an increased dynamic range.

The camera module controller 1216 may provide a control signal to each of the camera modules 1100a, 1100b, and 1100c. A control signal generated by the camera module controller 1216 may be provided to a corresponding one of the camera modules 1100a, 1100b, and 1100c through a corresponding one of control signal lines CSLa, CSLb, and CSLc, which are separated from one another.

One (e.g., the camera module 1100b) of the camera modules 1100a, 1100b, and 1100c may be designated as a master camera according to the mode signal or the image generation signal including a zoom signal, and the other camera modules (e.g., the camera modules 1100a and 1100c) may be designated as slave cameras. Such designation information may be included in a control signal and provided to each of the camera modules 1100a, 1100b, and 1100c through a corresponding one of the control signal lines CSLa, CSLb, and CSLc, which are separated from one another.

A camera module operating as a master or a slave may be changed according to a zoom factor or an operation mode signal. For example, when the field-of-view of the camera module 1100a is greater than that of the camera module 1100b and the zoom factor indicates a low zoom ratio, the camera module 1100b may operate as a master and the camera module 1100a may operate as a slave. Contrarily, when the zoom factor indicates a high zoom ratio, the camera module 1100a may operate as a master and the camera module 1100b may operate as a slave.

In one or more embodiments, a control signal provided from the camera module controller 1216 to each of the camera modules 1100a, 1100b, and 1100c may include a sync enable signal. For example, when the camera module 1100b is a master camera and the camera modules 1100a and 1100c are slave cameras, the camera module controller 1216 may transmit the sync enable signal to the camera module 1100b. The camera module 1100b provided with the sync enable signal may generate a sync signal based on the sync enable signal and may provide the sync signal to the camera modules 1100a and 1100c through a sync signal line SSL. The camera modules 1100a, 1100b, and 1100c may be synchronized with the sync signal and may transmit image data to the application processor 1200.

In one or more embodiments, a control signal provided from the camera module controller 1216 to each of the camera modules 1100a, 1100b, and 1100c may include mode information according to the mode signal. The camera modules 1100a, 1100b, and 1100c may operate in a first operation mode or a second operation mode in relation with a sensing speed based on the mode information.

In the first operation mode, the camera modules 1100a, 1100b, and 1100c may generate an image signal at a first speed (e.g., at a first frame rate), encode the image signal at a second speed higher than the first speed (e.g., at a second frame rate higher than the first frame rate), and transmit an encoded image signal to the application processor 1200. In this case, the second speed may be 30 times or less the first speed.

The application processor 1200 may store the received image signal (i.e., the encoded image signal) in the internal memory 1230 therein or the external memory 1400 outside the application processor 1200. Thereafter, the application processor 1200 may read the encoded image signal from the internal memory 1230 or the external memory 1400, decode the encoded image signal, and display image data generated based on a decoded image signal. For example, a corresponding one of the sub-processors 1212a, 1212b, and 1212c of the image processing device 1210 may perform the decoding and may also perform image processing on the decoded image signal.

In the second operation mode, the camera modules 1100a, 1100b, and 1100c may generate an image signal at a third speed lower than the first speed (e.g., at a third frame rate lower than the first frame rate) and transmit the image signal to the application processor 1200. The image signal provided to the application processor 1200 may not have been encoded. The application processor 1200 may perform image processing on the image signal or store the image signal in the internal memory 1230 or the external memory 1400.

The PMIC 1300 may provide power (e.g., a power supply voltage) to each of the camera modules 1100a, 1100b, and 1100c. For example, under control by the application processor 1200, the PMIC 1300 may provide first power to the camera module 1100a through a power signal line PSLa, second power to the camera module 1100b through a power signal line PSLb, and third power to the camera module 1100c through a power signal line PSLc.

The PMIC 1300 may generate power corresponding to each of the camera modules 1100a, 1100b, and 1100c and adjust the level of the power, in response to a power control signal PCON from the application processor 1200. The power control signal PCON may include a power adjustment signal for each operation mode of the camera modules 1100a, 1100b, and 1100c. For example, the operation mode may include a low-power mode. In this case, the power control signal PCON may include information about a camera module configured to operate in the low-power mode and a power level to be set. The same or different levels of power may be respectively provided to the camera modules 1100a, 1100b, and 1100c. The level of power may be dynamically changed.

In one or more example, embodiments, an image sensor and an electronic system implementing an image sensor may be provided, in which problems (e.g., shift, collapse, and/or deformation) of a pixel isolation structure and peripheral components thereof during and/or after the manufacture of the image sensor are prevented, Furthermore, the image sensor may have a structure that may effectively control characteristics (e.g., a dark current and white spots) and improve sensitivity in each of a plurality of unit pixels.

At least one of the devices, units, components, modules, units, or the like represented by a block or an equivalent indication in the above embodiments including, but not limited to, FIGS. 19A and 19B may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. An image sensor comprising:
a plurality of unit pixels on a substrate; and
a pixel isolation structure extending through the substrate in a vertical direction and defining the plurality of unit pixels,
wherein the pixel isolation structure comprises:
a line isolation portion linearly extending along a side of and between each of two adjacent unit pixels of the plurality of unit pixels;
a corner isolation portion contacting a corner of each of at least two adjacent unit pixels of the plurality of unit pixels;
a first conductive pattern surrounding a first air gap in the line isolation portion; and
a first insulating pattern surrounding the first air gap and the first conductive pattern in the line isolation portion, and
wherein a width of the first insulating pattern in a lateral direction varies along the vertical direction.

2. The image sensor of claim 1, wherein the pixel isolation structure further comprises:
a second conductive pattern in the corner isolation portion, the second conductive pattern being integrally connected to the first conductive pattern;
a second insulating pattern in the corner isolation portion, the second insulating pattern being surrounded by the second conductive pattern and integrally connected to the first insulating pattern;
a wiring structure on a frontside surface of the substrate; and
a plurality of color filters and a plurality of microlenses on a backside surface of the substrate, the backside surface being opposite to the frontside surface of the substrate, and
wherein at least one of the first insulating pattern and the second insulating pattern has a tapered cross-sectional shape with a width gradually increasing in the lateral direction from the backside surface of the substrate toward the frontside surface of the substrate.

3. The image sensor of claim 2, wherein at least one of the first conductive pattern and the second conductive pattern has a width gradually increasing in the lateral direction from the frontside surface of the substrate toward the backside surface of the substrate.

4. The image sensor of claim 1, wherein the first conductive pattern is at least partially exposed to the first air gap in the line isolation portion of the pixel isolation structure.

5. The image sensor of claim 4, further comprising an inner insulating film between the first conductive pattern and the first air gap in the line isolation portion of the pixel isolation structure,
wherein the inner insulating film comprises a silicon oxide film, a polysilicon film, a silicon nitride film, a metal oxide film, or a combination thereof.

6. The image sensor of claim 1, wherein the pixel isolation structure further comprises:
a second conductive pattern in the corner isolation portion, the second conductive pattern being integrally connected to the first conductive pattern;
a second insulating pattern in the corner isolation portion, the second insulating pattern being surrounded by the second conductive pattern and integrally connected to the first insulating pattern;
a second air gap in the corner isolation portion, the second air gap being surrounded by the second conductive pattern; and
an inner insulating film between the second conductive pattern and the second air gap in the corner isolation portion, and
wherein the inner insulating film comprises a silicon oxide film, a polysilicon film, a silicon nitride film, a metal oxide film, or a combination thereof.

7. The image sensor of claim 1, wherein the pixel isolation structure further comprises:
a second conductive pattern in the corner isolation portion, the second conductive pattern being integrally connected to the first conductive pattern;
a second insulating pattern in the corner isolation portion, the second insulating pattern being surrounded by the second conductive pattern and integrally connected to the first insulating pattern; and
a polysilicon plug surrounded by the second conductive pattern and contacting the second conductive pattern in the corner isolation portion.

8. The image sensor of claim 1, wherein the pixel isolation structure further comprises:
a second conductive pattern in the corner isolation portion, the second conductive pattern being integrally connected to the first conductive pattern;
a second insulating pattern in the corner isolation portion, the second insulating pattern surrounding the second conductive pattern and being integrally connected to the first insulating pattern;
a second air gap surrounded by the second conductive pattern in the corner isolation portion; and
a polysilicon liner between the second conductive pattern and the second air gap in the corner isolation portion, the polysilicon liner contacting the second conductive pattern.

9. The image sensor of claim 1, wherein the first conductive pattern comprises doped polysilicon.

10. The image sensor of claim 1, wherein the pixel isolation structure further comprises a local device isolation film extending through a portion of the substrate in the vertical direction, the local device isolation film covering at least a portion of an outer sidewall of the first insulating pattern, and
wherein a width of the first conductive pattern in the lateral direction gradually decreases toward the local device isolation film in the vertical direction.

11. The image sensor of claim 1, wherein the pixel isolation structure further comprises a local device isolation film extending through a portion of the substrate in the vertical direction, the local device isolation film covering at least a portion of an outer sidewall of the first insulating pattern,
wherein the first conductive pattern comprises a pair of inclined patterns inclined in mutually opposite directions with respect to the vertical direction, and
wherein the pair of inclined patterns of the first conductive pattern contact each other at a position at which the pair of inclined patterns of the first conductive pattern are closest to the local device isolation film.

12. The image sensor of claim 1, wherein the pixel isolation structure further comprises a local device isolation film extending through a portion of the substrate in the vertical direction, the local device isolation film covering at least a portion of an outer sidewall of the first insulating pattern,
wherein the first conductive pattern comprises a pair of inclined patterns inclined in mutually opposite directions with respect to the vertical direction, and
wherein the pair of inclined patterns of the first conductive pattern are spaced apart from each other at a position at which the pair of inclined patterns of the first conductive pattern are closest to the local device isolation film.

13. An image sensor comprising:
a plurality of unit pixels in a substrate comprising a frontside surface and a backside surface, each of the plurality of unit pixels respectively comprising a photodiode and the plurality of unit pixels having a two-dimensional array structure in a matrix form along a plurality of row lines and a plurality of column lines; and
a pixel isolation structure comprising:
a main device isolation film extending through the substrate from the frontside surface of the substrate to the backside surface of the substrate in a vertical direction and defining the plurality of unit pixels, the main device isolation film comprising a line isolation portion and a corner isolation portion;
a local device isolation film extending through a portion of the substrate from the frontside surface of the substrate in the vertical direction and covering at least as portion of a sidewall of the main device isolation film which is adjacent to the frontside surface of the substrate;
a first conductive pattern surrounding a first air gap in the line isolation portion;
a first insulating pattern surrounding the first air gap and the first conductive pattern in the line isolation portion;
a second conductive pattern in the corner isolation portion, the second conductive pattern being integrally connected to the first conductive pattern; and
a second insulating pattern in the corner isolation portion, the second insulating pattern surrounding the second conductive pattern and being integrally connected to the first insulating pattern,
wherein each of the first insulating pattern and the second insulating pattern has a tapered cross-sectional shape with a width gradually increasing in a lateral direction from the backside surface of the substrate toward the frontside surface of the substrate, and
wherein each of the first conductive pattern and the second conductive pattern has a width gradually increasing in the lateral direction from the frontside surface of the substrate toward the backside surface of the substrate.

14. The image sensor of claim 13, wherein the second conductive pattern surrounds a second air gap in the corner isolation portion,
wherein the pixel isolation structure further comprises an inner insulating structure between the second conductive pattern and the second air gap in the corner isolation portion,
wherein the inner insulating structure comprises a portion contacting the second conductive pattern and a portion facing the local device isolation film with the second insulating pattern therebetween in the lateral direction,
wherein the first conductive pattern comprises a pair of inclined patterns inclined in mutually opposite directions with respect to the vertical direction,
wherein the second conductive pattern comprises a pair of inclined patterns inclined in mutually opposite directions with respect to the vertical direction;
wherein the pair of inclined patterns of the first conductive pattern contact each other at a position at which the pair of inclined patterns of the first conductive pattern are closest to the local device isolation film, and
wherein the pair of inclined patterns of the second conductive pattern are spaced apart from each other at a position at which the pair of inclined patterns of the second conductive pattern are closest to the local device isolation film.

15. The image sensor of claim 13, wherein the pixel isolation structure further comprises:
a polysilicon plug surrounded by the second conductive pattern in the corner isolation portion, the polysilicon plug contacting the second conductive pattern; and
a third insulating pattern overlapping the polysilicon plug in the vertical direction in the corner isolation portion and contacting each of the polysilicon plug and the second conductive pattern, the third insulating pattern comprising a portion facing the local device isolation film with the second insulating pattern therebetween in the lateral direction,
wherein the first conductive pattern comprises a pair of inclined patterns inclined in mutually opposite directions with respect to the vertical direction,
wherein the second conductive pattern comprises a pair of inclined patterns inclined in mutually opposite directions with respect to the vertical direction;
wherein the pair of inclined patterns of the first conductive pattern contact each other at a position at which the pair of inclined patterns of the first conductive pattern are closest to the local device isolation film, and
wherein the pair of inclined patterns of the second conductive pattern are spaced apart from each other at a position at which the pair of inclined patterns of the second conductive pattern are closest to the local device isolation film.

16. The image sensor of claim 13, wherein the pixel isolation structure further comprises:
a polysilicon plug surrounded by the second conductive pattern in the corner isolation portion, the polysilicon plug contacting the second conductive pattern; and
a third insulating pattern overlapping the polysilicon plug in the vertical direction in the corner isolation portion and contacting each of the polysilicon plug and the second conductive pattern, the third insulating pattern comprising a portion facing the local device isolation film with the second insulating pattern therebetween in the lateral direction,
wherein the first conductive pattern comprises a pair of inclined patterns inclined in mutually opposite directions with respect to the vertical direction,
wherein the second conductive pattern comprises a pair of inclined patterns inclined in mutually opposite directions with respect to the vertical direction,
wherein the pair of inclined patterns of the first conductive pattern are spaced apart from each other at a position at which the pair of inclined patterns of the first conductive pattern are closest to the local device isolation film, and
wherein the pair of inclined patterns of the second conductive pattern are spaced apart from each other at a position at which the pair of inclined patterns of the second conductive pattern are closest to the local device isolation film.

17. The image sensor of claim 13, wherein the second conductive pattern surrounds a second air gap in the corner isolation portion,
wherein the pixel isolation structure further comprises:
a polysilicon liner between the second conductive pattern and the second air gap in the corner isolation portion, the polysilicon liner contacting the second conductive pattern; and
a third insulating pattern overlapping the polysilicon liner and the second air gap in the vertical direction in the corner isolation portion and contacting each of the polysilicon liner and the second conductive pattern, the third insulating pattern comprising a portion facing the local device isolation film with the second insulating pattern therebetween in the lateral direction,
wherein the first conductive pattern comprises a pair of inclined patterns inclined in mutually opposite directions with respect to the vertical direction,
wherein the second conductive pattern comprises a pair of inclined patterns inclined in mutually opposite directions with respect to the vertical direction,
wherein the pair of inclined patterns of the first conductive pattern are spaced apart from each other at a position at which the pair of inclined patterns of the first conductive pattern are closest to the local device isolation film, and
wherein the pair of inclined patterns of the second conductive pattern are spaced apart from each other at a position at which the pair of inclined patterns of the second conductive pattern are closest to the local device isolation film.

18. The image sensor of claim 13, wherein each of the first conductive pattern and the second conductive pattern comprises doped polysilicon.

19. The image sensor of claim 13, wherein the second conductive pattern surrounds a second air gap in the corner isolation portion,
wherein the pixel isolation structure further comprises an inner insulating film between the second conductive pattern and the second air gap in the corner isolation portion,
wherein the first conductive pattern is at least partially exposed to the first air gap in the line isolation portion of the pixel isolation structure,
wherein the inner insulating film is at least partially exposed to the second air gap in the corner isolation portion of the pixel isolation structure,
wherein each of the first conductive pattern and the second conductive pattern comprises doped polysilicon, and
wherein the inner insulating film comprises a silicon oxide film, a polysilicon film, a silicon nitride film, a metal oxide film, or a combination thereof.

20. An electronic system comprising:
at least one camera module comprising an image sensor; and
a processor configured to process image data provided by the at least one camera module,
wherein the image sensor comprises:
a plurality of unit pixels on a substrate; and
a pixel isolation structure extending through the substrate in a vertical direction and defining the plurality of unit pixels,
wherein the pixel isolation structure comprises:
a line isolation portion linearly extending along a side of and between each of two adjacent unit pixels of the plurality of unit pixels;
a corner isolation portion contacting a corner of each of at least two adjacent unit pixels of the plurality of unit pixels;
a first conductive pattern surrounding a first air gap in the line isolation portion; and
a first insulating pattern surrounding the first air gap and the first conductive pattern in the line isolation portion, and
wherein a width of the first insulating pattern in a lateral direction varies along the vertical direction.
